(19) United States
(12) Patent Application Publication
(10) Pub. No.: US 2026/0032880 A1
(43) Pub. Date: Jan. 29, 2026

(54) SEMICONDUCTOR PACKAGE STRUCTURE AND FABRICATION METHOD THEREOF

(71) Applicant: Yangtze Memory Technologies Holding Co., Ltd., Wuhan (CN)

(72) Inventors: Min Wen, Wuhan (CN); Liang Xiao, Wuhan (CN); Lina Miao, Wuhan (CN); Wenbin Zhou, Wuhan (CN); Zongliang Huo, Wuhan (CN)

(73) Assignee: Yangtze Memory Technologies Holding Co., Ltd., Wuhan (CN)

(21) Appl. No.: 18/935,238

(22) Filed: Nov. 1, 2024

(30) Foreign Application Priority Data
Jul. 23, 2024 (CN) 202410997972.6

(51) Int. Cl. H01L 23/00; H01L 25/065; H10B 12/00; H10B 80/00

(52) U.S. Cl. CPC H01L 24/13; H01L 24/16; H01L 24/32; H01L 24/73; H01L 24/80; H01L 25/0657; H10B 12/02; H10B 80/00; H01L 2224/13005; H01L 2224/13082; H01L 2224/13147; H01L 2224/13541; H01L 2224/13655; H01L 2224/16146; H01L 2224/3213; H01L 2224/73253; H01L 2224/80895; H01L 2224/80896; H01L 2225/06513; H01L 2225/06541; H01L 2924/1436

(57) ABSTRACT

According to one aspect, a semiconductor package structure is provided. The semiconductor package structure includes: a plurality of first semiconductor chips arranged as being stacked along a first direction, the first semiconductor chip includes at least one first conductive structure, the first conductive structure includes a first connection structure extending along the first direction, a second connection structure extending along the first direction, and an interconnection structure between the first connection structure and the second connection structure in the first direction, and the interconnection structure is connected with both the first connection structure and the second connection structure; and a first bump connection layer between two adjacent ones of the first semiconductor chips in the first direction, the first bump connection layer includes at least one first bump structure, and the first bump structure is coupled with each of the first conductive structures in the two adjacent first semiconductor chips.

### CROSS-REFERENCE TO RELATED APPLICATIONS

This application claims the benefit of priority to Chinese Application No. 202410997972.6, filed on Jul. 23, 2024, which is incorporated herein by reference in its entirety.

### TECHNICAL FIELD

The present disclosure relates to the field of semiconductor technology, e.g., to a semiconductor package structure and a fabrication method thereof.

### BACKGROUND

With the continuous development of the current science and technology, semiconductor devices are widely applied in various electronic apparatuses and electronic products. For example, a dynamic random-access memory (DRAM) as a volatile memory is a commonly used semiconductor memory device in a computer.

### SUMMARY

According to one aspect of the present disclosure, a semiconductor package structure may be provided. The semiconductor package structure may include a plurality of first semiconductor chips arranged as being stacked along a first direction. The first semiconductor chip may include at least one first conductive structure. The first conductive structure may include a first connection structure extending along the first direction, a second connection structure extending along the first direction, and an interconnection structure between the first connection structure and the second connection structure in the first direction. The interconnection structure may be connected with both the first connection structure and the second connection structure. The semiconductor package structure may include a first bump connection layer between two adjacent ones of the first semiconductor chips in the first direction. The first bump connection layer may include at least one first bump structure. The first bump structure may be coupled with each of the first conductive structures in the two adjacent ones of the first semiconductor chips.

In some implementations, the first bump structure may include a first bump and a second bump stacked along the first direction. In some implementations, the first bump may include a first portion and a second portion. In some implementations, the second bump may include a third portion and a fourth portion. In some implementations, the second portion may be located between the first portion and the third portion. In some implementations, the third portion may be located between the second portion and the fourth portion.

In some implementations, a material of the first portion may be different from a material of the second portion, and a material of the third portion may be different from a material of the fourth portion.

In some implementations, each of the material of the first portion and the material of the fourth portion may include copper, and each of the material of the second portion and the material of the third portion may include nickel.

In some implementations, the first portion may include a first sub-portion and a second sub-portion. In some implementations, the fourth portion may include a third sub-portion and a fourth sub-portion. In some implementations, the second sub-portion may be located between the first sub-portion and the second portion. In some implementations, the third sub-portion may be located between the fourth sub-portion and the third portion. In some implementations, a size of the first sub-portion along a second direction may be smaller than a size of the second sub-portion along the second direction. In some implementations, a size of the fourth sub-portion along the second direction may be smaller than a size of the third sub-portion along the second direction. In some implementations the second direction may be perpendicular to the first direction.

In some implementations, the interconnection structure may include a first interconnection sub-structure. In some implementations, a first bonding structure and a second interconnection sub-structure may be arranged as being stacked along the first direction. In some implementations, the first interconnection sub-structure may be located between the first connection structure and the first bonding structure. In some implementations, the second interconnection sub-structure may be located between the second connection structure and the first bonding structure.

In some implementations, the first semiconductor chip may include a first semiconductor structure, a first bonding layer, and a second semiconductor structure arranged as being stacked along the first direction. In some implementations, the first semiconductor structure may include the first connection structure, the first interconnection sub-structure and a memory array. In some implementations, the second semiconductor structure may include the second connection structure, the second interconnection sub-structure, and a peripheral circuit. In some implementations, the first bonding layer may include the first bonding structure and a second bonding structure, and the memory array may be coupled with the peripheral circuit through the second bonding structure.

In some implementations, the first semiconductor chip may include a memory region and a contact region arranged in juxtaposition along a direction perpendicular to the first direction. In some implementations, the at least one first conductive structure may be located in the contact region. In some implementations, the memory array and the peripheral circuit may be located in the memory region.

In some implementations, the second semiconductor structure may include a semiconductor layer extending along the direction perpendicular to the first direction. In some implementations, a partial structure of the peripheral circuit may be located in the semiconductor layer in the memory region. In some implementations, the second connection structure may extend through the semiconductor layer in the contact region along the first direction.

In some implementations, the second semiconductor structure further may include an isolation layer between the second connection structure and the semiconductor layer.

In some implementations, the first semiconductor structure further may include a first pad-out layer on one of two opposite sides of the memory array along the first direction away from the peripheral circuit and on one of two opposite sides of the first connection structure along the first direction away from the second connection structure. In some implementations, the first pad-out layer may include a first interconnection line and a first lead-out pad. In some implementations, two opposite ends of one of the first lead-out pads along the first direction may be connected with one of the first connection structures and one of the first bump structures, respectively. In some implementations, the first interconnection line may be coupled with both the memory array and the peripheral circuit.

In some implementations, a material of the first connection structure may be different from a material of the second connection structure, and a material of the first lead-out pad may be different from a material of the first connection structure.

In some implementations, a size of one of two opposite ends of the first connection structure in the first direction close to the second connection structure in the second direction may be smaller than a size of one of two opposite ends of the first connection structure in the first direction away from the second connection structure in the second direction. In some implementations, a size of one of two opposite ends of the second connection structure in the first direction close to the first connection structure in the second direction may be greater than a size of one of two opposite ends of the second connection structure in the first direction away from the first connection structure in the second direction. In some implementations, the second direction may be perpendicular to the first direction.

In some implementations, the first semiconductor structure may further include a wiring layer between the first bonding layer and the memory array and between the first bonding layer and the first connection structure. In some implementations, the wiring layer may include the first interconnection sub-structure and a first wiring between the memory array and the peripheral circuit. In some implementations, the first semiconductor structure may further include a third connection structure extending along the first direction. In some implementations, two opposite ends of the third connection structure along the first direction may be connected with the first wiring and the first interconnection line, respectively.

In some implementations, a size of the third connection structure in the first direction may be equal to a size of the first connection structure in the first direction.

In some implementations, the memory array may include a plurality of memory cells. In some implementations, the memory cell may include a capacitor structure and a transistor structure arranged as being stacked along the first direction. In some implementations, the capacitor structure may include a first plate, a second plate, and a dielectric layer between the first plate and the second plate. In some implementations, the transistor structure may include a gate structure and a semiconductor body extending along the first direction. In some implementations, one of two opposite ends of the semiconductor body along the first direction may be connected with the first plate of the capacitor structure. In some implementations, the second plate of the capacitor structure may be coupled with the first interconnection line. In some implementations, the semiconductor body may include a first electrode structure, a channel structure, and a second electrode structure arranged sequentially along the first direction. In some implementations, the gate structure may be located on at least one side of the channel structure along a direction perpendicular to the first direction. In some implementations, the gate structures of a plurality of transistor structures arranged along a third direction may be connected to form a word line structure extending along the third direction, and the third direction may be perpendicular to the first direction.

In some implementations, the second semiconductor structure may further include a second pad-out layer on one of two opposite sides of the peripheral circuit along the first direction away from the memory array and on one of two opposite sides of the second connection structure along the first direction away from the first connection structure. In some implementations, the second pad-out layer may include a second interconnection line and a second lead-out pad. In some implementations, two opposite ends of one of the second lead-out pads along the first direction may be connected with one of the second connection structures and one of the first bump structures, respectively. In some implementations, the second interconnection line may be coupled with both the memory array and the peripheral circuit.

In some implementations, the semiconductor package structure may include a second semiconductor chip arranged as being stacked with the plurality of first semiconductor chips along the first direction. In some implementations, the second semiconductor chip may include a third semiconductor structure and a fourth semiconductor structure arranged as being stacked along the first direction. In some implementations, the third semiconductor structure may be located between the fourth semiconductor structure and the first semiconductor chip. In some implementations, one of two opposite sides of the third semiconductor structure along the first direction away from the fourth semiconductor structure may include a third pad-out layer that may include at least one third lead-out pad. In some implementations, the semiconductor package structure may include a second bump connection layer between the first semiconductor chip closest to the second semiconductor chip and the second semiconductor chip. In some implementations, the second bump connection layer may include at least one second bump structure. In some implementations, the second bump structure may be coupled with the third lead-out pad and coupled with the first conductive structure of the first semiconductor chip closest to the second semiconductor chip.

In some implementations, the semiconductor package structure may include a third semiconductor chip arranged as being stacked with the plurality of first semiconductor chips along the first direction. In some implementations, the third semiconductor chip may include a control circuit, and the plurality of first semiconductor chips may be located between the second semiconductor chip and the third semiconductor chip. In some implementations, the semiconductor package structure may include a third bump connection layer between the third semiconductor chip and the first semiconductor chip closest to the third semiconductor chip in the first direction. In some implementations, the third bump connection layer may include at least one third bump structure, and the third bump structure may be coupled with the first conductive structure and coupled with the control circuit.

According to another aspect of the present disclosure, a semiconductor package device may be provided. The semiconductor package device may include a plurality of first semiconductor chips arranged as being stacked along a first direction and a first bump connection layer between two adjacent ones of the first semiconductor chips in the first direction. The first semiconductor chip may include a first semiconductor structure, a first bonding layer, and a second semiconductor structure arranged as being stacked along the first direction, and at least one connection structure. The connection structure may extend through the first bonding layer along the first direction and may extend into the first semiconductor structure and the second semiconductor structure. The first bump connection layer may include at least one first bump structure. The first bump structure may be coupled with each of the connection structures in the two adjacent ones of the first semiconductor chips.

In some implementations, the first bump structure may include a first bump and a second bump stacked along the first direction. In some implementations, the first bump may include a first portion and a second portion. In some implementations, the second bump may include a third portion and a fourth portion. In some implementations, the second portion may be located between the first portion and the third portion. In some implementations, the third portion may be located between the second portion and the fourth portion.

In some implementations, a material of the first portion may be different from a material of the second portion, and a material of the third portion may be different from a material of the fourth portion.

In some implementations, each of the material of the first portion and the material of the fourth portion both may include copper, and each of the material of the second portion and the material of the third portion may include nickel.

In some implementations the first portion may include a first sub-portion and a second sub-portion. In some implementations, the fourth portion may include a third sub-portion and a fourth sub-portion. In some implementations, the second sub-portion may be located between the first sub-portion and the second portion. In some implementations, the third sub-portion may be located between the fourth sub-portion and the third portion. In some implementations, a size of the first sub-portion along a second direction may be smaller than a size of the second sub-portion along the second direction. In some implementations, a size of the fourth sub-portion along the second direction may be smaller than a size of the third sub-portion along the second direction, and the second direction may be perpendicular to the first direction.

In some implementations, the first semiconductor chip may include a memory region and a contact region arranged in juxtaposition along a direction perpendicular to the first direction. In some implementations, the contact region may include at least one connection structure. In some implementations, the memory region may include a memory array and a peripheral circuit arranged as being stacked along the first direction, and at least one second bonding structure between the memory array and the peripheral circuit. In some implementations, the second bonding structure may be coupled with both the memory array and the peripheral circuit. In some implementations, the memory array may be located in the first semiconductor structure. In some implementations, the peripheral circuit may be located in the second semiconductor structure. In some implementations, the second bonding structure may be located in the first bonding layer.

In some implementations, the second semiconductor structure may include a semiconductor layer extending along the direction perpendicular to the first direction. In some implementations, a partial structure of the peripheral circuit may be located in the semiconductor layer in the memory region. In some implementations, the connection structure may extend through the semiconductor layer in the contact region along the first direction.

In some implementations, the second semiconductor structure may further include an isolation layer between the connection structure and the semiconductor layer.

In some implementations, the first semiconductor structure may further include a first pad-out layer on one of two opposite sides of the memory array along the first direction away from the peripheral circuit and extending from the memory region into the contact region along the direction perpendicular to the first direction. In some implementations the first pad-out layer may include a first interconnection line and a first lead-out pad, two opposite ends of one of the first lead-out pads along the first direction may be connected with one of the connection structures and one of the first bump structures, respectively. In some implementations, the first interconnection line may be coupled with both the memory array and the peripheral circuit.

In some implementations, the memory array may include a plurality of memory cells. In some implementations, the memory cell may include a capacitor structure and a transistor structure arranged as being stacked along the first direction. In some implementations, the capacitor structure may include a first plate, a second plate, and a dielectric layer between the first plate and the second plate. In some implementations, the transistor structure may include a gate structure and a semiconductor body extending along the first direction. In some implementations, one of two opposite ends of the semiconductor body along the first direction may be connected with the first plate of the capacitor structure. In some implementations, the second plate of the capacitor structure may be coupled with the first interconnection line. In some implementations, the semiconductor body may include a first electrode structure, a channel structure, and a second electrode structure arranged sequentially along the first direction. In some implementations, the gate structure may be located on at least one side of the channel structure along the direction perpendicular to the first direction. In some implementations, the gate structures of a plurality of transistor structures arranged along a third direction may be connected to form a word line structure extending along the third direction. In some implementations, the third direction may be perpendicular to the first direction.

In some implementations, semiconductor package structure may further include a second semiconductor chip arranged as being stacked with the plurality of first semiconductor chips along the first direction. In some implementations, the second semiconductor chip may include a third semiconductor structure and a fourth semiconductor structure arranged as being stacked along the first direction. In some implementations, the third semiconductor structure may be located between the fourth semiconductor structure and the first semiconductor chip. In some implementations, one of two opposite sides of the third semiconductor structure along the first direction away from the fourth semiconductor structure may include a third pad-out layer that may include at least one third lead-out pad. In some implementations, semiconductor package structure may further include a second bump connection layer between the first semiconductor chip closest to the second semiconductor chip and the second semiconductor chip. In some implementations, the second bump connection layer may include at least one second bump structure. In some implementations, the second bump structure may be coupled with the third lead-out pad and coupled with the connection structure of the first semiconductor chip closest to the second semiconductor chip.

In some implementations, semiconductor package structure may further include a third semiconductor chip arranged as being stacked with the plurality of first semiconductor chips along the first direction. In some implementations, the third semiconductor chip may include a control circuit. In some implementations, the plurality of first semiconductor chips may be located between the second semiconductor chip and the third semiconductor chip. In some implementations, semiconductor package structure may further include a third bump connection layer between the third semiconductor chip and the first semiconductor chip closest to the third semiconductor chip in the first direction. In some implementations, the third bump connection layer may include at least one third bump structure, and the third bump structure may be coupled with the connection structure and coupled with the control circuit.

According to a further aspect of the present disclosure, a method of fabricating a semiconductor package structure may be provided. The method may include forming a plurality of first semiconductor chips. The first semiconductor chip may include at least one first conductive structure. The first conductive structure may include a first connection structure extending along a first direction, a second connection structure extending along the first direction, and an interconnection structure between the first connection structure and the second connection structure in the first direction. The interconnection structure may be connected with both the first connection structure and the second connection structure. The method may include arranging the plurality of first semiconductor chips as being stacked along the first direction, and forming a first bump connection layer including at least one first bump structure between two adjacent ones of the first semiconductor chips to couple the first conductive structures in the two adjacent ones of the first semiconductor chips through the first bump structure.

In some implementations, forming the first semiconductor chip may include forming a first semiconductor structure, including forming a memory array and a first interconnection sub-structure. In some implementations, forming the first semiconductor chip may include forming a first bonding sub-layer on one of two opposite sides of the first semiconductor structure along the first direction. In some implementations, forming the first semiconductor chip may include forming a second semiconductor structure, including forming a peripheral circuit, the second connection structure, and a second interconnection sub-structure connected with the second connection structure. In some implementations, forming the first semiconductor chip may include forming a second bonding sub-layer on one of two opposite sides of the second semiconductor structure along the first direction. In some implementations, forming the first semiconductor chip may include bonding the first bonding sub-layer with the second bonding sub-layer to form a first bonding layer between the first semiconductor structure and the second semiconductor structure. In some implementations, the first bonding layer may include a first bonding structure and a second bonding structure. In some implementations, the memory array may be coupled with the peripheral circuit through the second bonding structure. In some implementations, the first interconnection sub-structure may be coupled with the second interconnection sub-structure through the first bonding structure, and the first interconnection sub-structure. In some implementations, the second interconnection sub-structure and the first bonding structure may constitute the interconnection structure. In some implementations forming the first connection structure in the first semiconductor structure. In some implementations, the first connection structure may be connected with the first interconnection sub-structure.

In some implementations, the first semiconductor chip may include a memory region and a contact region arranged in juxtaposition along a direction perpendicular to the first direction. In some implementations, the at least one first conductive structure may be located in the contact region, and the memory array and the peripheral circuit may be located in the memory region.

In some implementations, the forming the second semiconductor structure further may include forming an initial semiconductor layer extending along the direction perpendicular to the first direction. In some implementations, the forming the second semiconductor structure further may include forming a partial structure of the peripheral circuit in the initial semiconductor layer in the memory region. In some implementations, the forming the second semiconductor structure further may include forming a second connection structure extending into the initial semiconductor layer in the contact region along the first direction. In some implementations, the forming the first semiconductor chip further may include removing part of the initial semiconductor structure from one of two opposite sides of the initial semiconductor layer along the first direction away from the first semiconductor structure to expose the second connection structure and form a semiconductor layer.

In some implementations, the forming the first semiconductor chip further may include forming a first pad-out layer on one of two opposite sides of the first connection structure along the first direction away from the second connection structure and on one of two opposite sides of the memory array along the first direction away from the peripheral circuit. In some implementations, the first pad-out layer may include a first interconnection line and a first lead-out pad. In some implementations, one of two opposite ends of one of the first lead-out pads along the first direction may be connected with one of the first connection structures. In some implementations, the first interconnection line may be coupled with both the memory array and the peripheral circuit.

In some implementations, forming the first bump connection layer may include forming a first bump connection sub-layer on one of two opposite sides of the first pad-out layer along the first direction away from the second semiconductor structure. forming a second bump connection sub-layer on one of two opposite sides of the semiconductor layer along the first direction away from the first semiconductor structure. In some implementations, forming the first bump connection layer may include bonding the first bump connection sub-layer on one of the first semiconductor chips with the second bump connection sub-layer on other one of the first semiconductor chips to form the first bump connection layer between two adjacent ones of the first semiconductor chips. In some implementations, the other one of two opposite ends of one of the first lead-out pads along the first direction may be connected with one of the first bump structures.

In some implementations, the forming the first semiconductor structure further may include forming a wiring layer on one of two opposite sides of the memory array along the first direction. In some implementations, the wiring layer may extend from the memory region into the contact region along the direction perpendicular to the first direction, and may include the first interconnection sub-structure and a first wiring. In some implementations, the forming the first semiconductor structure further may include forming a third connection structure extending along the first direction while forming the first connection structure. In some implementations, two opposite ends of the third connection structure along the first direction may be connected with the first wiring and the first interconnection line, respectively.

In some implementations, forming the memory array may include forming a plurality of memory cells. In some implementations, the memory cell may include a capacitor structure and a transistor structure arranged as being stacked along the first direction. In some implementations, the capacitor structure may include a first plate, a second plate, and a dielectric layer between the first plate and the second plate. In some implementations, the transistor structure may include a gate structure and a semiconductor body extending along the first direction. In some implementations, one of two opposite ends of the semiconductor body along the first direction may be connected with the first plate of the capacitor structure. In some implementations, the second plate of the capacitor structure may be coupled with the first interconnection line. In some implementations, the semiconductor body may include a first electrode structure, a channel structure, and a second electrode structure arranged sequentially along the first direction. In some implementations, the gate structure may be located on at least one side of the channel structure along the direction perpendicular to the first direction. In some implementations, the gate structures of a plurality of transistor structures arranged along a third direction may be connected to form a word line structure extending along the third direction, and the third direction may be perpendicular to the first direction.

In some implementations, the method may include forming a second semiconductor chip. In some implementations, the second semiconductor chip may include a third semiconductor structure and a fourth semiconductor structure arranged as being stacked along the first direction. In some implementations, one of two opposite sides of the third semiconductor structure along the first direction away from the fourth semiconductor structure may include a third pad-out layer that may include at least one third lead-out pad. In some implementations, the method may include stacking the second semiconductor chip on the plurality of first semiconductor chips, and forming a second bump connection layer between the first semiconductor chip closest to the second semiconductor chip and the second semiconductor chip. In some implementations, the third semiconductor structure may be located between the fourth semiconductor structure and the first semiconductor chip. In some implementations, the second bump connection layer may include at least one second bump structure. In some implementations, the second bump structure may be coupled with the third lead-out pad and coupled with the first conductive structure.

In some implementations, the method may further include forming a third semiconductor chip including a control circuit. In some implementations, the method may further include forming a third bump connection layer between the third semiconductor chip and one of the first semiconductor chips. In some implementations, the third bump connection layer may include a third bump structure. In some implementations, the third bump structure may be coupled with the first conductive structure and coupled with the control circuit. In some implementations, the plurality of first semiconductor chips may be located between the second semiconductor chip and the third semiconductor chip.

According to yet another aspect of the present disclosure, a method of fabricating a semiconductor package structure may be provided. The method may include forming a plurality of first semiconductor chips. The first semiconductor chip may include a first semiconductor structure, a first bonding layer, and a second semiconductor structure arranged as being stacked along a first direction, and at least one connection structure. The connection structure may extend through the first bonding layer along the first direction and may extend into the first semiconductor structure and the second semiconductor structure. The method may include arranging the plurality of first semiconductor chips as being stacked along the first direction, and forming a first bump connection layer including at least one first bump structure between two adjacent ones of the first semiconductor chips to couple the connection structures in the two adjacent ones of the first semiconductor chips may be coupled through the first bump structure.

In the technical solutions provided in the present disclosure, a plurality of first semiconductor chips may be arranged as being stacked along a first direction. The first semiconductor chip includes a first conductive structure or a connection structure extending along the first direction. Two adjacent ones of the first semiconductor chips are connected through a first bump connection layer. The first bump connection layer includes a first bump structure coupled with the first conductive structure or the connection structure so that the plurality of first semiconductor chips can be integrated in the first direction. Thus, the integration level of the semiconductor package structure can be increased and the memory capacity of the semiconductor package structure in unit area can be increased, thereby facilitating the miniaturization development of the semiconductor package structure.

### BRIEF DESCRIPTION OF THE DRAWINGS

FIG. 1 is a schematic diagram of an electronic apparatus provided by an example of the present disclosure;

FIG. 2 is a schematic diagram of a DRAM provided by an example of the present disclosure;

FIG. 3 is a schematic structural diagram I of a semiconductor package structure provided by an example of the present disclosure;

FIG. 4 is a schematic structural diagram of a first conductive structure provided by an example of the present disclosure;

FIG. 5 is a schematic structural diagram of a first bump structure provided by an example of the present disclosure;

FIG. 6 is a schematic structural diagram I of a first semiconductor chip provided by an example of the present disclosure;

FIG. 7 is a schematic diagram of a layout of first semiconductor chips provided by an example of the present disclosure;

FIG. 8 is a schematic enlarged view of a partial structure in FIG. 6;

FIG. 9 is a cross-sectional view of FIG. 8 along a line AA′;

FIG. 10 is a schematic structural diagram II of a semiconductor package structure provided by an example of the present disclosure;

FIG. 11 is a schematic structural diagram III of a semiconductor package structure provided by an example of the present disclosure;

FIG. 12 is a schematic structural diagram of a semiconductor package structure provided by another example of the present disclosure;

FIG. 13 is a schematic structural diagram of a first semiconductor chip provided by another example of the present disclosure;

FIG. 14 is a flow chart of a method of fabricating a semiconductor package structure provided by an example of the present disclosure;

FIGS. 15 to 28 are schematic structural diagrams of a fabrication process of a semiconductor package structure provided by an example of the present disclosure;

FIG. 29 is a flow chart of a method of fabricating a semiconductor package structure provided by another example of the present disclosure; and

FIGS. 30 to 32 are schematic structural diagrams of a fabrication process of a semiconductor package structure provided by another example of the present disclosure.

### DETAILED DESCRIPTION

Exemplary implementations disclosed in the present disclosure will be described in more detail with reference to the drawings. Although the exemplary implementations of the present disclosure are shown in the drawings, it is to be understood that the present disclosure may be implemented in various forms and should not be limited by the specific implementations set forth herein. Rather, these implementations are provided for a more thorough understanding of the present disclosure, and to fully convey a scope disclosed by the present disclosure to those skilled in the art.

In the following description, numerous specific details are given in order to provide a more thorough understanding of the present disclosure. However, it is apparent to those skilled in the art that the present disclosure may be implemented without one or more of these details. In other examples, in order to avoid confusion with the present disclosure, some technical features well-known in the field are not described. That is, not all the features of the actual examples are described herein, and well-known functions and structures are not described in detail.

In the drawings, like reference numerals denote like elements throughout the specification.

It is to be understood that the spatially relative terms, such as “beneath”, “below”, “lower”, “under”, “over”, “upper”, etc., may be used here for ease of description to describe the relationship between one element or feature and other elements or features as illustrated in the figures. It is to be understood that the spatially relative terms are intended to further encompass different orientations of a device in use or operation in addition to the orientation depicted in the figures. For example, if the device in the drawings is flipped, then the elements or the features described as “below” or “under” or “beneath” other elements may be oriented “on” the other elements or features. Thus, the example terms “below” and “beneath” may comprise both upper and lower orientations. The device may be orientated otherwise (rotated by 90 degrees or other orientations), and the spatially descriptive words used here are interpreted accordingly.

The terms used here are only intended to describe the specific examples, and are not used as limitations to the present disclosure. As used here, unless otherwise indicated expressly in the context, “a”, “an” and “the” in a singular form are also intended to comprise a plural form. It should also be understood that terms “consist of” and/or “comprise”, when used in this specification, determine the presence of the described features, integers, steps, operations, elements and/or components, but do not preclude the presence or addition of one or more other features, integers, steps, operations, elements, components, and/or groups. As used here, a term “and/or” comprises any and all combinations of related items listed.

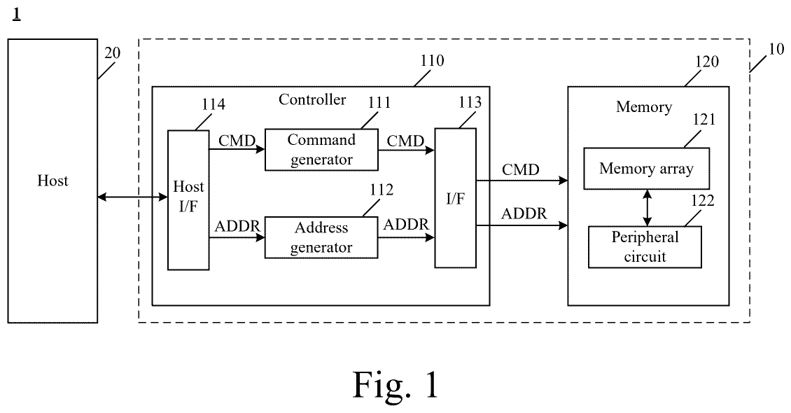

FIG. 1 is a schematic diagram of an electronic apparatus provided by an example of the present disclosure. The electronic apparatus 1 may be a mobile phone, a desktop computer, a laptop computer, a tablet computer, a vehicle computer, a gaming console, a printer, a positioning apparatus, a wearable electronic apparatus, a smart sensor, a virtual reality (VR) apparatus, an augmented reality (AR) apparatus, or any other suitable electronic apparatuses having memories therein.

As shown in FIG. 1, the electronic apparatus 1 may include a memory system 10 and a host 20. The memory system 10 may include a controller 110 and a memory 120. The host 20 may include a processor of the electronic apparatus 1 (e.g., a central processing unit (CPU)) or a system on chip (SoC) (e.g., an application processor (AP)). The controller 110 is coupled with both the host 20 and the memory 120. The controller 110 may be configured to communicate with the host 20 and control the memory 120.

In some examples, the controller 110 may be configured to control operations of the memory 120, such as a read operation, an erase operation, a write operation, a refresh operation and the like. In some implementations, the controller 110 is further configured to process an error correction code (ECC) with respect to the data read from or written to the memory 120. In some other implementations, the controller 110 may be further configured to perform any other suitable operations, for example, formatting the memory 120.

In some examples, the controller 110 may receive data, a command and an address from the host 20 and may send data, a command and an address to the memory 120. In an example, the controller 110 may include a command generator 111, an address generator 112, an apparatus interface 113, and a host interface 114. The controller 110 may receive data, a command and an address from the host 20 through the host interface 114 and decode the command received from the host 20 through the command generator 111 to generate an access command CMD, and may provide the access command CMD to the memory 120 through the apparatus interface 113. The controller 110 may decode the address received from the host interface 114 through the address generator 112 to generate an address ADDR to be accessed in a memory array 121, and may provide the address ADDR to be accessed to the memory 120 through the apparatus interface 113. The access command may be a signal that instructs the memory 120 to write or read data by accessing one or more memory cells in the memory array 121 corresponding to the address ADDR. Moreover, the controller 110 may further send a refresh command to the memory 120. The refresh command may be a signal that instructs the memory 120 to read and re-write data by accessing one or more memory cells in the memory array 121 corresponding to the address ADDR.

In some particular examples, the memory 120 may be a random-access memory (RAM), such as a dynamic random-access memory, a synchronous dynamic random access memory (SDRAM), a static random access memory (SRAM), a dual date rate SDRAM (DDR SDRAM), a phase-change random access memory (PRAM), a resistive random access memory (RcRAM), a magnetic random access memory (MRAM), and the like. The following description will be made by using an example that the memory 120 is the DRAM.

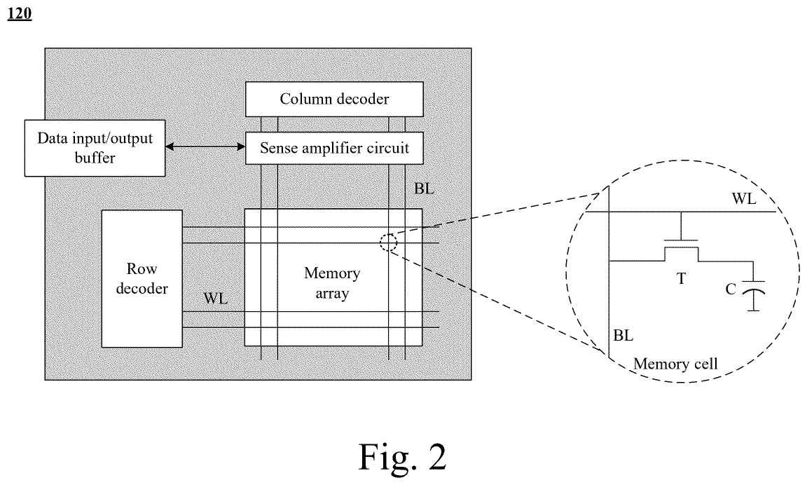

In some examples, FIG. 2 is a schematic diagram of a DRAM illustrated by an example of the present disclosure. With reference to FIGS. 1 and 2 in combination, the DRAM includes a memory array 121 and a peripheral circuit 122 coupled with the memory array 121. The peripheral circuit 122 may include a sense amplifier circuit, a row decoder, a column decoder, a data input/output buffer, and the like. The memory array 121 includes a plurality of memory cells arranged in an array. A plurality of memory cells in the same row are coupled with a word line WL, and a plurality of memory cells in the same column are coupled with a bit line BL. Each memory cell includes one transistor T and one capacitor C. The word line WL is connected with a gate of the transistor T. The bit line BL is connected with one of a source and a drain of the transistor T. The other one of the source and the drain of the transistor T is connected with one electrode of the capacitor C. The other electrode of the capacitor C is connected with a fixed voltage. The memory cell is configured to store 1 or 0 according to an amount of charge stored in the capacitor C. By designating a row address and a column address, individual memory cells in a DRAM chip may be independently accessed, and a read operation, a write perform or a refresh operation may be performed on the data stored therein.

With increasing requirement for an integration level of a memory, how to increase the integration level of the memory has become a problem urgently to be solved. In this regard, the present disclosure provides the following implementations.

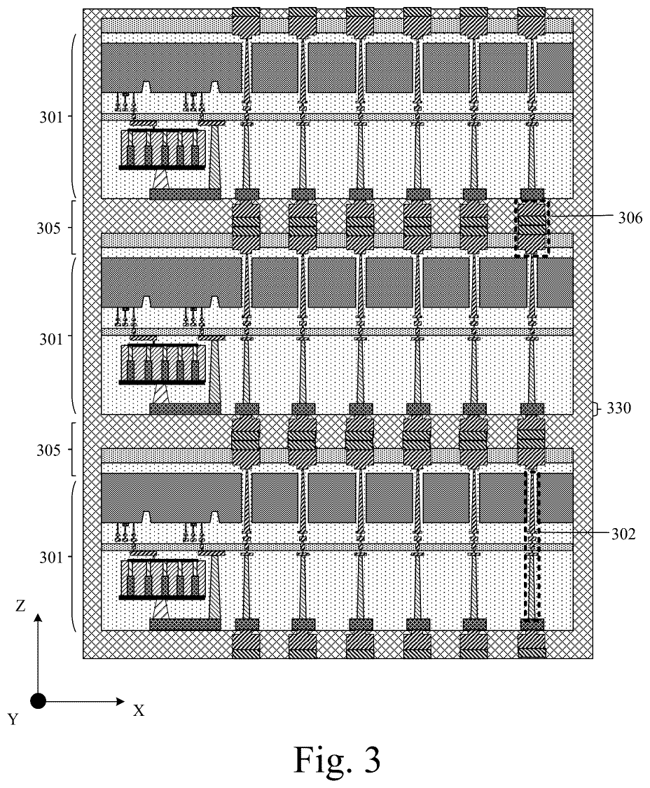

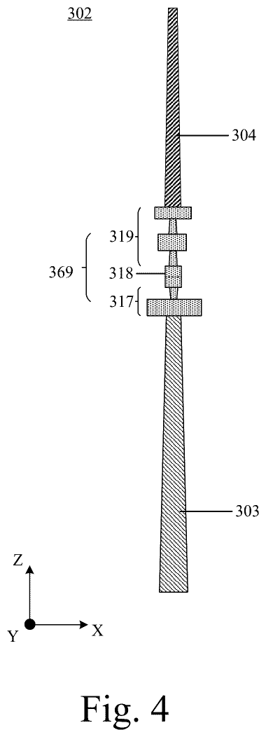

An example of the present disclosure provides a semiconductor package structure. FIG. 3 is a schematic structural diagram of a semiconductor package structure provided by an example of the present disclosure, and FIG. 4 is a schematic structural diagram of a first conductive structure 302 provided by an example of the present disclosure. As shown in FIGS. 3 and 4, the semiconductor package structure includes a plurality of first semiconductor chips 301 arranged as being stacked along a first direction. The first semiconductor chip 301 includes at least one first conductive structure 302. The first conductive structure 302 includes a first connection structure 303 extending along the first direction, a second connection structure 304 extending along the first direction, and an interconnection structure 369 between the first connection structure 303 and the second connection structure 304 in the first direction. The interconnection structure 369 is connected with both the first connection structure 303 and the second connection structure 304. The semiconductor package structure further includes a first bump connection layer 305 between two adjacent ones of the first semiconductor chips 301 in the first direction. The first bump connection layer 305 includes at least one first bump structure 306. The first bump structure 306 is coupled with each of the first conductive structures 302 in the two adjacent ones of the first semiconductor chips 301. Here, the first direction may be a Z direction.

It is to be noted that both the number of the first semiconductor chips 301 and the number of the first conductive structures 302 in each first semiconductor chip 301 in the figures are merely examples. The present disclosure has no particular limitations on the number of the first semiconductor chips 301 and the number of the first conductive structures 302 in each first semiconductor chip 301.

In some examples, as shown in FIG. 4, the interconnection structure 369 includes a first interconnection sub-structure 317, a first bonding structure 318 and a second interconnection sub-structure 319 arranged as being stacked along the first direction. The first interconnection sub-structure 317 is located between the first connection structure 303 and the first bonding structure 318, and the second interconnection sub-structure 319 is located between the second connection structure 304 and the first bonding structure 318.

Here, each of the first interconnection sub-structure 317 and the second interconnection sub-structure 319 may include a plurality of conductive layers and conductive contact structures connected with the conductive layers. Both the number of the conductive layers and the number of the conductive contact structures as shown are merely schematic.

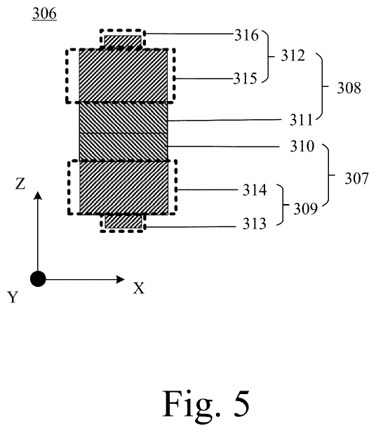

In some examples, FIG. 5 is a schematic structural diagram of a first bump structure 306. The first bump connection layer 305 includes at least one first bump structure 306. As shown in FIG. 5, the first bump structure 306 includes a first bump 307 and a second bump 308 stacked along the first direction. The first bump 307 includes a first portion 309 and a second portion 310. The second bump 308 includes a third portion 311 and a fourth portion 312. The second portion 310 is located between the first portion 309 and the third portion 311. The third portion 311 is located between the second portion 310 and the fourth portion 312.

In some particular examples, a material of the first bump structure 306 includes a conductive material, such as tungsten, cobalt, copper, aluminum, nickel, a silicide or any combination thereof.

In some examples, a material of the first portion 309 is different from a material of the second portion 310; and a material of the third portion 311 is different from a material of the fourth portion 312.

In some particular examples, the material of the second portion 310 may be the same as the material of the third portion 311. The material of the first portion 309 may be the same as the material of the fourth portion 312.

In some examples, each of the material of the first portion 309 and the material of the fourth portion 312 may include copper, and each of the material of the second portion 310 and the material of the third portion 311 may include nickel.

It is to be noted that the materials of the first portion 309, the fourth portion 312, the second portion 310 and the third portion 311 shown in the above examples are merely examples and are not intended to limit the particular materials of the first portion 309, the fourth portion 312, the second portion 310 and the third portion 311 in the examples of the present disclosure.

In an example of the present disclosure, the first bump includes the first portion and the second portion, and the second bump includes the third portion and the fourth portion. The first portion and the second portion are made of different materials, and the third portion and the fourth portion are made of different materials, and each of the third portion and the second portion is made of nickel. In this way, when bonding, the first bump and the second bump can be fused more easily so that the difficulty of bonding can be reduced.

In some examples, as shown in FIG. 5, the first portion 309 includes a first sub-portion 313 and a second sub-portion 314. The fourth portion 312 includes a third sub-portion 315 and a fourth sub-portion 316. The second sub-portion 314 is located between the first sub-portion 313 and the second portion 310. The third sub-portion 315 is located between the fourth sub-portion 316 and the third portion 311. A size of the first sub-portion 313 along a second direction is smaller than a size of the second sub-portion 314 along the second direction, and a size of the fourth sub-portion 316 along the second direction is smaller than a size of the third sub-portion 315 along the second direction. The second direction is perpendicular to the first direction. Here, the second direction may be an X direction.

In some particular examples, the size of the second sub-portion 314 along the second direction may be equal to or not equal to the size of the second portion 310 along the second direction. The size of the third sub-portion 315 along the second direction may be equal to or not equal to the size of the third portion 311 along the second direction.

In some particular examples, the sizes of the first sub-portion 313 and the fourth sub-portion 316 along the second direction range from 3 μm to 8 μm. The sizes of the second sub-portion 314 and the third sub-portion 315 along the second direction range from 10 μm to 15 μm.

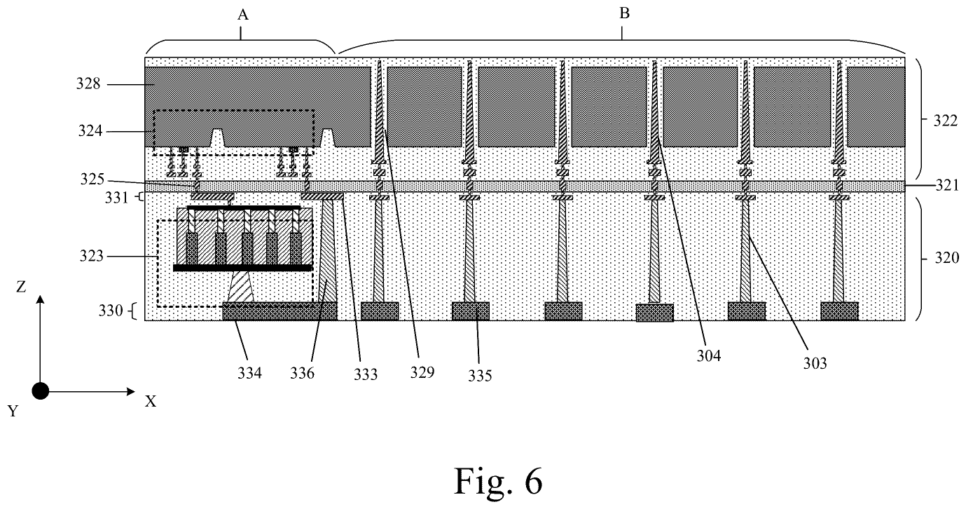

In some examples, as shown in FIGS. 6 and 4, the first semiconductor chip 301 includes a first semiconductor structure 320, a first bonding layer 321 and a second semiconductor structure 322 arranged as being stacked along the first direction. The first semiconductor structure 320 includes the first connection structure 303, the first interconnection sub-structure 317 and a memory array 323. The second semiconductor structure 322 includes the second connection structure 304, the second interconnection sub-structure 319 and a peripheral circuit 324. The first bonding layer 321 includes the first bonding structure 318 and a second bonding structure 325. The memory array 323 is coupled with the peripheral circuit 324 through the second bonding structure 325.

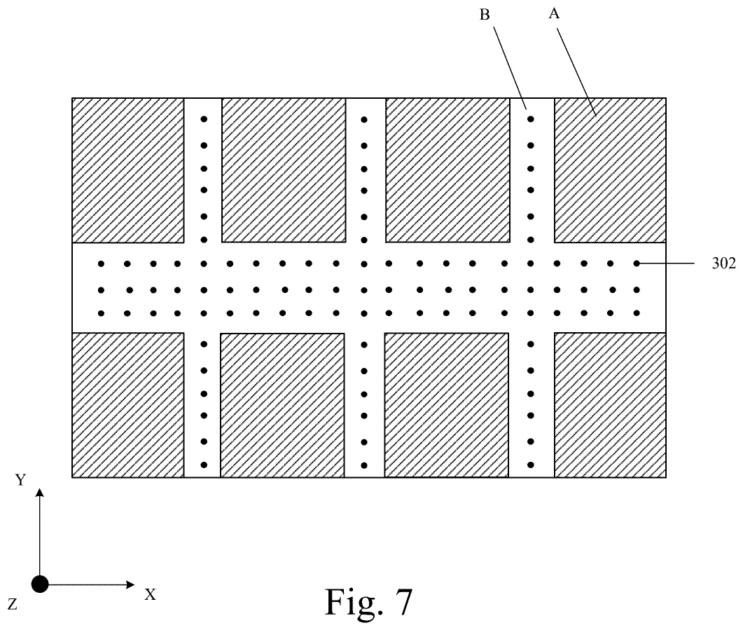

In some examples, FIG. 7 is a schematic diagram of a layout of first semiconductor chips 301 provided by an example of the present disclosure. With reference to FIGS. 6 and 7 in combination, the first semiconductor chip 301 includes a memory region A and a contact region B arranged in juxtaposition along a direction perpendicular to the first direction. The at least one first conductive structure 302 is located in the contact region B. The memory array 323 and the peripheral circuit 324 are located in the memory region A. It is to be noted that a distribution manner of the memory region A and the contact region B in FIG. 7 is merely an example.

In some particular examples, the first bonding layer 321 may be a hybrid bonding layer, and each of the first bonding structures 318 and the second bonding structure 325 may be a metal-metal bonding structure.

In an example of the present disclosure, the first semiconductor structure 320 and the second semiconductor structure 322 in the first semiconductor chip 301 are connected through the first bonding layer 321, thus the memory array 323 and the peripheral circuit 324 may be arranged along a stacking direction of the chip. On the one hand, the length of a connection line between the memory array 323 and the peripheral circuit 324 may be reduced and the reliability of signal transmission may be improved. On the other hand, the area of the memory region A may be reduced, which facilitates the miniaturization development of the semiconductor package structure.

In some examples, as shown in FIG. 6, the second semiconductor structure 322 includes a semiconductor layer 328 extending along the direction perpendicular to the first direction. A partial structure of the peripheral circuit 324 is located in the semiconductor layer 328 in the memory region A. The second connection structure 304 extends through the semiconductor layer 328 in the contact region B along the first direction.

In some particular examples, the semiconductor layer 328 may be a substrate. A material of the substrate may include at least one of semiconductor materials such as silicon, germanium, silicon germanium and the like. The peripheral circuit 324 may include a plurality of CMOS transistors. An active region of the CMOS transistor may be located in the semiconductor layer 328. A gate structure and a gate dielectric layer of the CMOS transistor are located on a side of the semiconductor layer 328. The gate dielectric layer is located between the gate structure and the active region.

In some examples, as shown in FIG. 6, the second semiconductor structure 322 further includes an isolation layer 329 between the second connection structure 304 and the semiconductor layer 328.

In some particular examples, a material of the isolation layer 329 includes, but is not limited to, silicon nitride and silicon oxide.

In some examples, with reference to FIGS. 3 and 6 in combination, the first semiconductor structure 320 further includes a first pad-out layer 330 on one of two opposite sides of the memory array 323 along the first direction away from the peripheral circuit 324 and on one of two opposite sides of the first connection structure 303 along the first direction away from the second connection structure 304. The first pad-out layer 330 includes a first interconnection line 334 and a first lead-out pad 335. Two opposite ends of one of the first lead-out pads 335 along the first direction are connected with one of the first connection structures 303 and one of the first bump structures 306, respectively. The first interconnection line 334 is coupled with both the memory array 323 and the peripheral circuit 324.

In some examples, each of materials of the first connection structure 303, the second connection structure 304, the interconnection structure 369 and the first lead-out pad 335 includes a conductive material. Here, the conductive material may be one of a doped semiconductor material (e.g., doped silicon, doped germanium, etc.), a conductive metal nitride (e.g., titanium nitride, tantalum nitride, etc.), a metal material (e.g., aluminum, copper, tungsten, titanium, tantalum, etc.), and a metal semiconductor compound (e.g., tungsten silicide, cobalt silicide, titanium silicide, etc.).

In some examples, the material of the first connection structure 303 may be different from the material of the second connection structure 304. The material of the first lead-out pad 335 may be different from the material of the first connection structure 303.

In a particular example, the material of the first connection structure 303 includes tungsten. Each of the material of the second connection structure 304 and the material of the interconnection structure 369 includes copper. The material of the first lead-out pad 335 includes aluminum.

In some examples, as shown in FIGS. 3 and 6, a size of one of two opposite ends of the first connection structure 303 in the first direction close to the second connection structure 304 in the second direction is smaller than a size of one of two opposite ends of the first connection structure 303 in the first direction away from the second connection structure 304 in the second direction. A size of one of two opposite ends of the second connection structure 304 in the first direction close to the first connection structure 303 in the second direction is greater than a size of one of two opposite ends of the second connection structure 304 in the first direction away from the first connection structure 303 in the second direction. The second direction is perpendicular to the first direction. Here, the second direction may be an X direction.

In some examples, with continued reference to FIG. 6, the first semiconductor structure 320 further includes a wiring layer 331 between the first bonding layer 321 and the memory array 323 and between the first bonding layer 321 and the first connection structure 303. The wiring layer 331 includes the first interconnection sub-structure 317, and a first wiring 333 between the memory array 323 and the peripheral circuit 324. The first semiconductor structure 320 further includes a third connection structure 336 extending along the first direction. Two opposite ends of the third connection structure 336 along the first direction are connected with the first wiring 333 and the first interconnection line 334, respectively.

In some examples, a size of the third connection structure 336 in the first direction is equal to a size of the first connection structure 303 in the first direction. It is to be noted that the size of the third connection structure 336 in the first direction being equal to the size of the first connection structure 303 in the first direction refers to the sizes of the two being substantially equal within an allowable process error range.

In some examples, a material of the third connection structure 336 includes a conductive material. Here, the conductive material may be one of a doped semiconductor material (e.g., doped silicon, doped germanium, etc.), a conductive metal nitride (e.g., titanium nitride, tantalum nitride, etc.), a metal material (e.g., aluminum, copper, tungsten, titanium, tantalum, etc.), and a metal semiconductor compound (e.g., tungsten silicide, cobalt silicide, titanium silicide, etc.).

In some particular examples, the material of the third connection structure 336 may be the same as the material of the first connection structure 303.

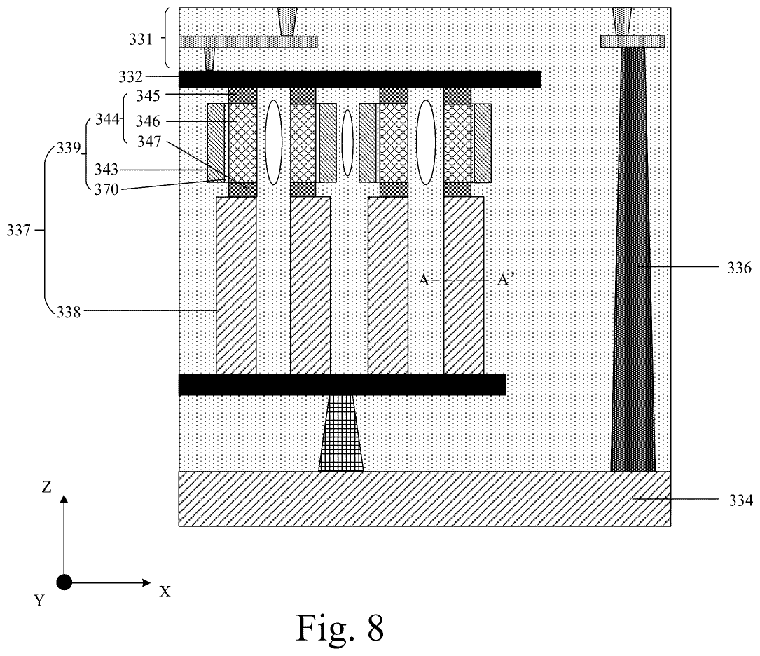

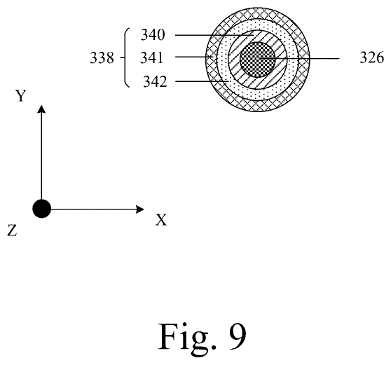

In some examples, FIG. 8 is a schematic enlarged view of a partial structure in FIG. 6, and FIG. 9 is a cross-sectional view of FIG. 8 along a line AA′. With reference to FIGS. 6, 8 and 9 in combination, the memory array 323 includes a plurality of memory cells 337. The memory cell 337 includes a capacitor structure 338 and a transistor structure 339 arranged as being stacked along the first direction. The capacitor structure 338 includes a first plate 340, a second plate 341, and a dielectric layer 342 between the first plate 340 and the second plate 341, as well as a support structure 326. The transistor structure 339 includes a gate structure 343 and a semiconductor body 344 extending along the first direction. One of two opposite ends of the semiconductor body 344 along the first direction is connected with the first plate 340 of the capacitor structure 338. The second plate 341 of the capacitor structure 338 is coupled with the first interconnection line 334.

It is to be noted that the specific structure of the capacitor structure 338 shown in FIGS. 8 and 9 is merely an example. In some examples, the capacitor structure may not include the support structure and may include only the first plate, the second plate, and the dielectric layer between the first plate and the second plate. In some other examples, the capacitor structure may further include any other suitable structure, which is not particularly limited in the present disclosure.

In some particular examples, with reference FIG. 8, the semiconductor body 344 includes a first electrode structure 345, a channel structure 346 and a second electrode structure 347 arranged sequentially along the first direction. The gate structure 343 is located on at least one side of the channel structure 346 along the direction perpendicular to the first direction. The gate structures 343 of a plurality of transistor structures 339 arranged along a third direction are connected to form a word line structure extending along the third direction. The third direction is perpendicular to the first direction. Here, the third direction is a Y direction. Here, the first electrode structure 345 may be one of the source or the drain of the transistor structure. The second electrode structure 347 may be the other one of the source or the drain of the transistor structure.

In some particular examples, the first plate 340 may be used as a lower electrode of a memory capacitor, and the second plate 341 may be used as an upper electrode of the memory capacitor. A material of the dielectric layer 342 includes a high dielectric constant (high-K) material. In an example, the material of the dielectric layer 342 may include, but is not limited to, aluminum oxide (Al₂O₃), zirconium oxide (ZrO), hafnium oxide (HfO₂), etc. A material of the first plate 340 may include a conductive material, for example, may be titanium nitride. A material of the second plate 341 may include a conductive material, for example, may be titanium nitride or silicon germanium.

It is to be noted that the examples of the present disclosure are described by using an example that the memory cell 337 includes one capacitor and one transistor (1T1C), but the present disclosure is not limited thereto. The memory cell 337 in the present disclosure may also be an nTOC capacitor-less architecture, architectures such as 1TnC and 2TnC, etc., which is not limited in the present disclosure.

In some particular examples, the second electrode structures 347 of a plurality of transistor structures 339 arranged along the second direction may be connected with a bit line structure 332 extending along the second direction. The bit line structure 332 may be further connected with the wiring layer 331. Here, the second direction and the third direction are both perpendicular to the first direction. The second direction may be the X direction, and the third direction may be the Y direction.

It is to be noted that the way in which the gate structure 343 is disposed in FIG. 8 is merely an example. In some other examples, the gate structure 343 may be located on one side, two sides or three sides of the channel structure 346, or surround the channel structure 346, which is not particularly limited in the present disclosure.

In some particular examples, a material of the semiconductor body 344 includes, but is not limited to, an elementary semiconductor material (e.g., silicon (Si) or germanium (Ge), etc.), a III-V compound semiconductor material (e.g., gallium nitride (GaN), gallium arsenide (GaAs), or indium phosphide (InP), etc.), a II-VI compound semiconductor material (e.g., zinc sulfide (ZnS), cadmium sulfide (CdS) or cadmium telluride (CdTe), etc.), an organic semiconductor material or other semiconductor materials known in the art.

In some particular examples, a material of the gate structure 343 includes a conductive material, such as at least one of a doped semiconductor material (e.g., doped silicon, doped germanium, etc.), a conductive metal nitride (e.g., titanium nitride, tantalum nitride, etc.), a metal material (e.g., aluminum, copper, tungsten, titanium, tantalum, etc.), and a metal semiconductor compound (e.g., tungsten silicide, cobalt silicide, titanium silicide, etc.).

As shown in FIG. 8, the transistor structure 339 further includes a gate dielectric layer 370 between the gate structure 343 and the channel structure 346. The gate dielectric layer 370 may include at least one of a high dielectric constant material, silicon oxide, silicon nitride and silicon oxynitride, where the high dielectric constant material may include at least one of hafnium oxide, hafnium silicon oxide, lanthanum oxide, zirconium oxide, zirconium silicon oxide, tantalum oxide, titanium oxide, barium strontium titanium oxide, barium titanium oxide, strontium titanium oxide, lithium oxide, aluminum oxide, lead scandium tantalum oxide, and lead zinc niobate.

In an example of the present disclosure, the memory cell 337 in the memory array 323 is composed of the transistor structure 339 and the capacitor structure 338. The transistor structure 339 is a vertical transistor including a semiconductor body 344 extending along the first direction, which facilitates the further reduction of the area of the memory region A and the increase of the memory density. Moreover, an extending direction of the memory cell 337, a stacking direction of the chip, a stacking direction of the memory array 323 and the peripheral circuit 324 and an extending direction of the first conductive structure 302 are the same, which facilitates the three-dimensional integration of the semiconductor package structure.

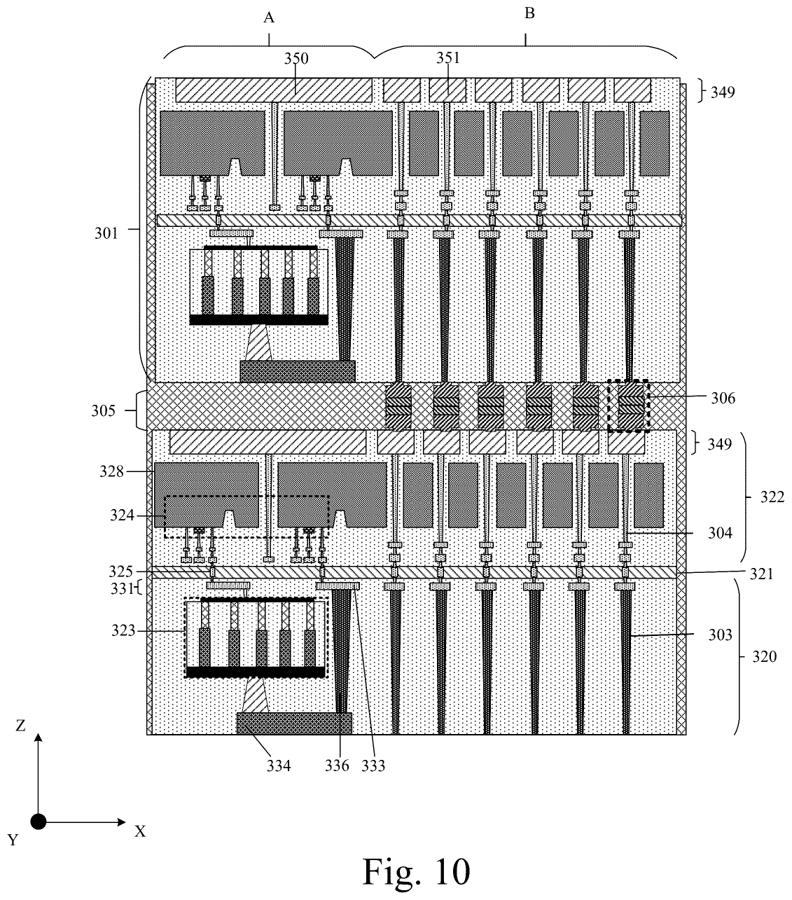

In the above examples, it is used as an example that the pad-out layer is disposed on a side of the memory array 323 away from the peripheral circuit 324. In some other examples, the pad-out layer may further be disposed on a side of the peripheral circuit 324 away from the memory array 323. FIG. 10 is a schematic structural diagram of two adjacent first semiconductor chips 301. As shown in FIG. 10, the second semiconductor structure 322 further includes a second pad-out layer 349 on one of two opposite sides of the peripheral circuit 324 along the first direction away from the memory array 323 and on one of two opposite sides of the second connection structure 304 along the first direction away from the first connection structure 303. The second pad-out layer 349 includes a second interconnection line 350 and a second lead-out pad 351. Two opposite ends of one of the second lead-out pads 351 along the first direction are connected with one of the second connection structures 304 and one of the first bump structures 306, respectively. The second interconnection line 350 is coupled with both the memory array 323 and the peripheral circuit 324.

In some particular examples, when a memory device including the memory array 323 and the peripheral circuit 324 is led out from a side of the peripheral circuit 324, the size of one of two opposite ends of the first connection structure 303 in the first direction close to the second connection structure 304 in the second direction may be greater than the size of one of two opposite ends of the first connection structure 303 in the first direction away from the second connection structure 304 in the second direction. The size of one of two opposite ends of the second connection structure 304 in the first direction close to the first connection structure 303 in the second direction may be smaller than the size of one of two opposite ends of the second connection structure 304 in the first direction away from the first connection structure 303 in the second direction.

In some particular examples, a material of the second interconnection line 350 and a material of the second lead-out pad 351 each include a conductive material.

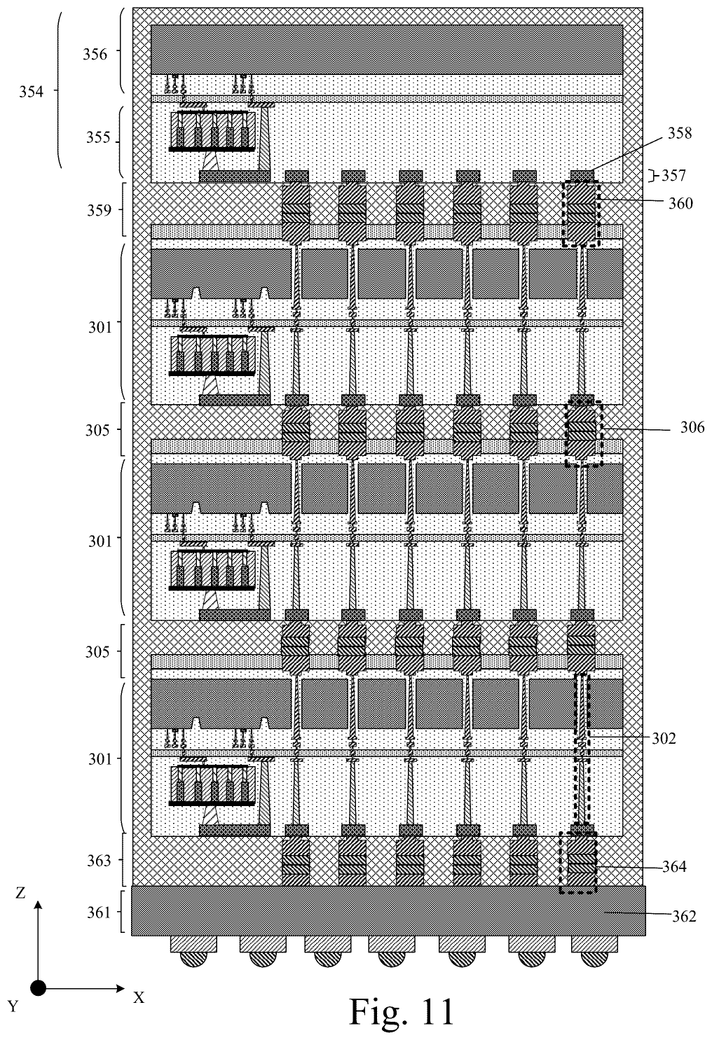

In some examples, a plurality of first semiconductor chips 301 may be further integrated with a second semiconductor chip and a third semiconductor chip. FIG. 11 is a schematic structural diagram of a semiconductor package structure including a plurality of first semiconductor chips 301, one second semiconductor chip 354 and one third semiconductor chip 361 provided by an example of the present disclosure.

In some examples, as shown in FIG. 11, the semiconductor package structure further includes a second semiconductor chip 354 arranged as being stacked with the plurality of first semiconductor chips 301 along the first direction. The second semiconductor chip 354 includes a third semiconductor structure 355 and a fourth semiconductor structure 356 arranged as being stacked along the first direction. The third semiconductor structure 355 is located between the fourth semiconductor structure 356 and the first semiconductor chip 301. One of two opposite sides of the third semiconductor structure 355 along the first direction away from the fourth semiconductor structure 356 includes a third pad-out layer 357 that includes at least one third lead-out pad 358.

In some examples, as shown in FIG. 11, the semiconductor package structure further includes a second bump connection layer 359 between the first semiconductor chip 301 closest to the second semiconductor chip 354 and the second semiconductor chip 354. The second bump connection layer 359 includes at least one second bump structure 360. The second bump structure 360 is coupled with the third lead-out pad 358 and coupled with the first conductive structure 302 of the first semiconductor chip 301 closest to the second semiconductor chip 354.

Here, the second semiconductor chip 354 may be a memory chip at a topmost layer in a package structure. The second semiconductor chip 354 may have no first conductive structure 302 extending through the second semiconductor chip 354 along the first direction and configured to connect the second semiconductor chip 354 with other semiconductor chips. The memory array and the peripheral circuit in the second semiconductor chip 354 may be coupled with the first semiconductor chip 301 through the third lead-out pad 358 and the second bump connection layer 359.

In some examples, with continued reference to FIG. 11, the semiconductor package structure further includes a third semiconductor chip 361 arranged as being stacked with the plurality of first semiconductor chips 301 along the first direction. The third semiconductor chip 361 includes a control circuit 362. The plurality of first semiconductor chips 301 are located between the second semiconductor chip 354 and the third semiconductor chip 361.

In some examples, with continued reference to FIG. 11, the semiconductor package structure further includes a third bump connection layer 363 between the third semiconductor chip 361 and the first semiconductor chip 301 closest to the third semiconductor chip 361 in the first direction. The third bump connection layer 363 includes at least one third bump structure 364. The third bump structure 364 is coupled with the first conductive structure 302 and coupled with the control circuit 362.

In an example of the present disclosure, a plurality of semiconductor chips arranged as being stacked along the first direction may be connected through a bump connection layer. A bump structure in the bump connection layer may be connected with the first conductive structure 302 extending along the first direction and the first lead-out pad 335 in the first semiconductor chip 301. Thus, a plurality of memory chips may be coupled to the third semiconductor chip 361.

In some particular examples, one of two opposite sides of the third semiconductor chip 361 along the first direction away from the first semiconductor chip 301 may further include an external connection structure which may be configured to connect the semiconductor package structure with an interposer or a package substrate.

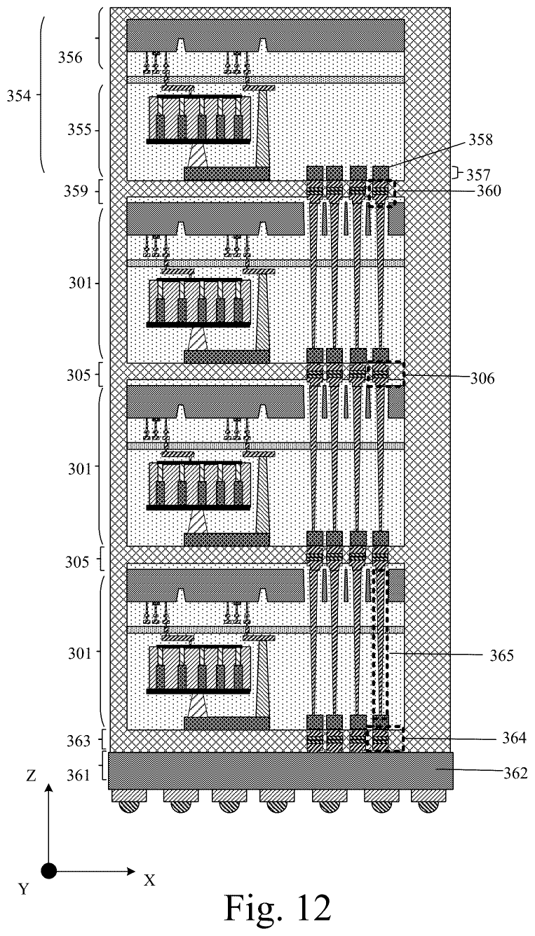

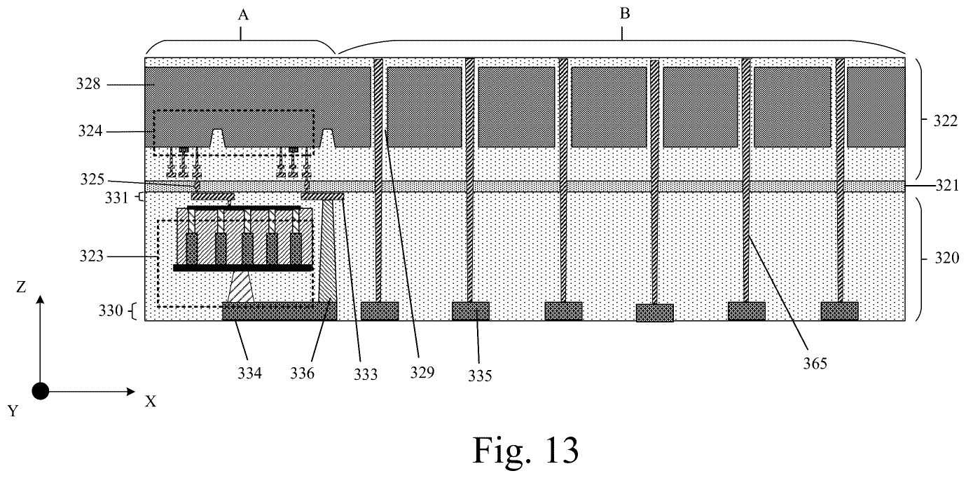

Based on the similar concept to the above semiconductor package structure, an example of the present disclosure further provides a semiconductor package structure. FIG. 12 is a schematic structural diagram of a semiconductor package structure. FIG. 13 is a schematic structural diagram of one first semiconductor chip 301 in the semiconductor package structure. With reference to FIGS. 12 and 13 in combination, the semiconductor package structure includes a plurality of first semiconductor chips 301 arranged as being stacked along a first direction and a first bump connection layer 305 between two adjacent ones of the first semiconductor chips 301 in the first direction, where the first semiconductor chip 301 includes a first semiconductor structure 320, a first bonding layer 321 and a second semiconductor structure 322 arranged as being stacked along the first direction, and at least one connection structure 365. The connection structure 365 extends through the first bonding layer 321 along the first direction and extends into the first semiconductor structure 320 and the second semiconductor structure 322. The first bump connection layer 305 includes at least one first bump structure 306. The first bump structure 306 is coupled with each of the connection structures 365 in the two adjacent ones of the first semiconductor chips 301.

In some particular examples, a material of the connection structure 365 includes a conductive material. Here, the conductive material may be one of a doped semiconductor material (e.g., doped silicon, doped germanium, etc.), a conductive metal nitride (e.g., titanium nitride, tantalum nitride, etc.), a metal material (e.g., aluminum, copper, tungsten, titanium, tantalum, etc.), and a metal semiconductor compound (e.g., tungsten silicide, cobalt silicide, titanium silicide, etc.).

In some examples, with reference to FIGS. 5 and 12 in combination, the first bump structure 306 includes a first bump 307 and a second bump 308 stacked along the first direction. The first bump 307 includes a first portion 309 and a second portion 310. The second bump 308 includes a third portion 311 and a fourth portion 312. The second portion 310 is located between the first portion 309 and the third portion 311. The third portion 311 is located between the second portion 310 and the fourth portion 312.

In some examples, a material of the first portion 309 is different from a material of the second portion 310; and a material of the third portion 311 is different from a material of the fourth portion 312.

In some examples, each of the material of the first portion 309 and the material of the fourth portion 312 may include copper, and each of the material of the second portion 310 and the material of the third portion 311 may include nickel.

In some examples, the first portion 309 includes a first sub-portion 313 and a second sub-portion 314. The fourth portion 312 includes a third sub-portion 315 and a fourth sub-portion 316. The second sub-portion 314 is located between the first sub-portion 313 and the second portion 310. The third sub-portion 315 is located between the fourth sub-portion 316 and the third portion 311. The size of the first sub-portion 313 along a second direction is smaller than the size of the second sub-portion 314 along the second direction, and the size of the fourth sub-portion 316 along the second direction is smaller than the size of the third sub-portion 315 along the second direction. The second direction is perpendicular to the first direction.

In some examples, the first semiconductor chip 301 includes a memory region A and a contact region B arranged in juxtaposition along a direction perpendicular to the first direction. The contact region B includes at least one connection structure 365. The memory region A includes a memory array 323 and a peripheral circuit 324 arranged as being stacked along the first direction, and at least one second bonding structure 325 between the memory array 323 and the peripheral circuit 324. The second bonding structure 325 is coupled with both the memory array 323 and the peripheral circuit 324. The memory array 323 is located in the first semiconductor structure 320. The peripheral circuit 324 is located in the second semiconductor structure 322. The second bonding structure 325 is located in the first bonding layer 321.

In some examples, as shown in FIG. 13, the second semiconductor structure 322 includes a semiconductor layer 328 extending along the direction perpendicular to the first direction. A partial structure of the peripheral circuit 324 is located in the semiconductor layer 328 in the memory region A. The connection structure 365 extends through the semiconductor layer 328 in the contact region B along the first direction.

In some particular examples, the semiconductor layer 328 may be a substrate. A material of the substrate may include at least one of semiconductor materials such as silicon, germanium, silicon germanium and the like. The peripheral circuit 324 may include a plurality of CMOS transistors. An active region of the CMOS transistor may be located in the semiconductor layer 328. A gate structure and a gate dielectric layer of the CMOS transistor are located on a side of the semiconductor layer 328. The gate dielectric layer is located between the gate structure and the active region.

In some examples, as shown in FIG. 13, the second semiconductor structure 322 further includes an isolation layer 329 between the connection structure 365 and the semiconductor layer 328.

In some examples, as shown in FIG. 13, the first semiconductor structure 320 further includes a first pad-out layer 330 on one of two opposite sides of the memory array 323 along the first direction away from the peripheral circuit 324 and extending from the memory region A into the contact region B along the direction perpendicular to the first direction. The first pad-out layer 330 includes a first interconnection line 334 and a first lead-out pad 335. Two opposite ends of one of the first lead-out pads 335 along the first direction are connected with one of the connection structures 365 and one of the first bump structures 306, respectively. The first interconnection line 334 is coupled with both the memory array 323 and the peripheral circuit 324.

In some examples, the memory array 323 includes a plurality of memory cells 337. The memory cell 337 includes a capacitor structure 338 and a transistor structure 339 arranged as being stacked along the first direction. The capacitor structure 338 includes a first plate 340, a second plate 341, and a dielectric layer 342 between the first plate 340 and the second plate 341. The transistor structure 339 includes a gate structure 343 and a semiconductor body 344 extending along the first direction. One of two opposite ends of the semiconductor body 344 along the first direction is connected with the first plate 340 of the capacitor structure 338. The second plate 341 of the capacitor structure 338 is coupled with the first interconnection line 334. The semiconductor body 344 includes a first electrode structure 345, a channel structure 346 and a second electrode structure 347 arranged sequentially along the first direction. The gate structure 343 is located on at least one side of the channel structure 346 along the direction perpendicular to the first direction. The gate structures 343 of a plurality of transistor structures 339 arranged along a third direction are connected to form a word line structure extending along the third direction. The third direction is perpendicular to the first direction.

In some examples, as shown in FIG. 12, the semiconductor package structure further includes: a second semiconductor chip 354 arranged as being stacked with the plurality of first semiconductor chips 301 along the first direction, where the second semiconductor chip 354 includes a third semiconductor structure 355 and a fourth semiconductor structure 356 arranged as being stacked along the first direction, the third semiconductor structure 355 is located between the fourth semiconductor structure 356 and the first semiconductor chip 301, and one of two opposite sides of the third semiconductor structure 355 along the first direction away from the fourth semiconductor structure 356 includes a third pad-out layer 357 that includes at least one third lead-out pad 358; and a second bump connection layer 359 between the first semiconductor chip 301 closest to the second semiconductor chip 354 and the second semiconductor chip 354, where the second bump connection layer 359 includes at least one second bump structure 360, and the second bump structure 360 is coupled with the third lead-out pad 358 and coupled with the connection structure 365 of the first semiconductor chip 301 closest to the second semiconductor chip 354.

Here, the second semiconductor chip 354 may be a memory chip at a topmost layer in a package structure. The second semiconductor chip 354 may have no connection structure 365 extending through the second semiconductor chip 354 along the first direction and configured to connect the second semiconductor chip 354 with other semiconductor chips. The memory array and the peripheral circuit in the second semiconductor chip 354 may be coupled with the first semiconductor chip 301 through the third lead-out pad 358 and the second bump connection layer 359.

In some examples, as shown in FIG. 12, the semiconductor package structure further includes: a third semiconductor chip 361 arranged as being stacked with the plurality of first semiconductor chips 301 along the first direction, where the third semiconductor chip 361 includes a control circuit 362, and the plurality of first semiconductor chips 301 are located between the second semiconductor chip 354 and the third semiconductor chip 361; and a third bump connection layer 363 between the third semiconductor chip 361 and the first semiconductor chip 301 closest to the third semiconductor chip 361 in the first direction, where the third bump connection layer 363 includes at least one third bump structure 364, and the third bump structure 364 is coupled with the connection structure 365 and coupled with the control circuit 362.

In the technical solutions provided in the present disclosure, the plurality of first semiconductor chips 301 are arranged as being stacked along the first direction. The first semiconductor chip 301 includes the first conductive structure 302 or the connection structure 365 extending along the first direction. Two adjacent ones of the first semiconductor chips 301 are connected through the first bump connection layer 305. The first bump connection layer 305 includes the first bump structure 306 coupled with the first conductive structure 302 or the connection structure 365 so that the plurality of first semiconductor chips can be integrated in the first direction. Thus, the integration level of the semiconductor package structure can be increased and the memory capacity of the semiconductor package structure in unit area can be increased, thereby facilitating the miniaturization development of the semiconductor package structure.

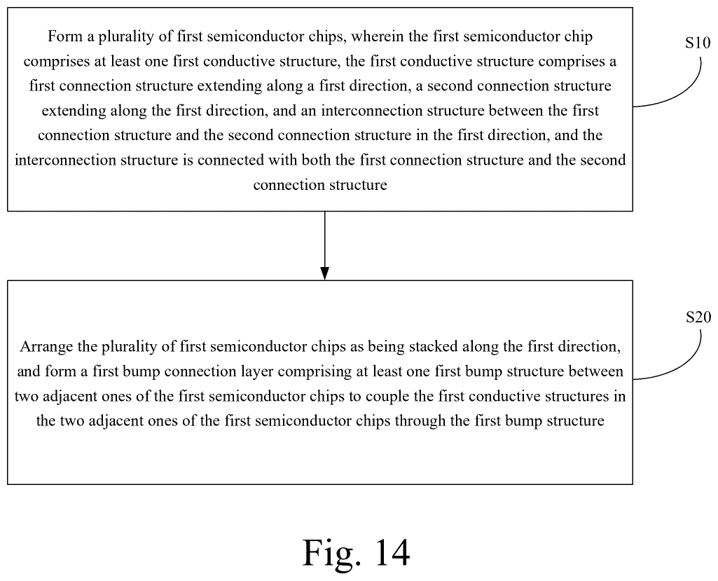

Based on the above-mentioned semiconductor package structure, an example of the present disclosure further provides a method of fabricating a semiconductor package structure. FIG. 14 is a flow chart of a method of fabricating a semiconductor package structure provided by an example of the present disclosure. As shown in FIG. 14, the method of fabricating the semiconductor package structure includes:
operation S10: forming a plurality of first semiconductor chips, where the first semiconductor chip includes at least one first conductive structure, the first conductive structure includes a first connection structure extending along a first direction, a second connection structure extending along the first direction, and an interconnection structure between the first connection structure and the second connection structure in the first direction, and the interconnection structure is connected with both the first connection structure and the second connection structure;
operation S20: arranging the plurality of first semiconductor chips as being stacked along the first direction, and forming a first bump connection layer including at least one first bump structure between two adjacent ones of the first semiconductor chips to couple the first conductive structures in the two adjacent ones of the first semiconductor chips through the first bump structure.

It is to be understood that operations illustrated in FIG. 14 are not exclusive, and other operations may be also performed before, after, or between any of the illustrated operations. A sequence of the operations illustrated in FIG. 14 can be adjusted according to actual needs.

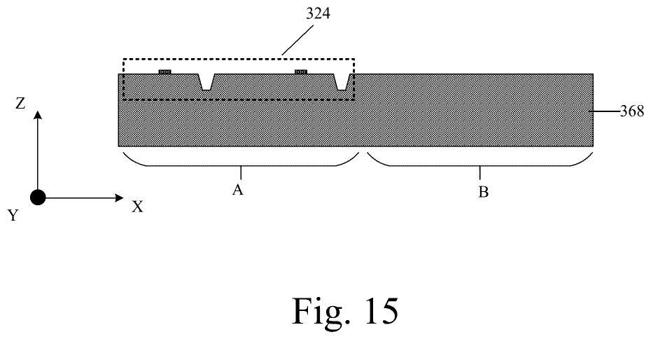

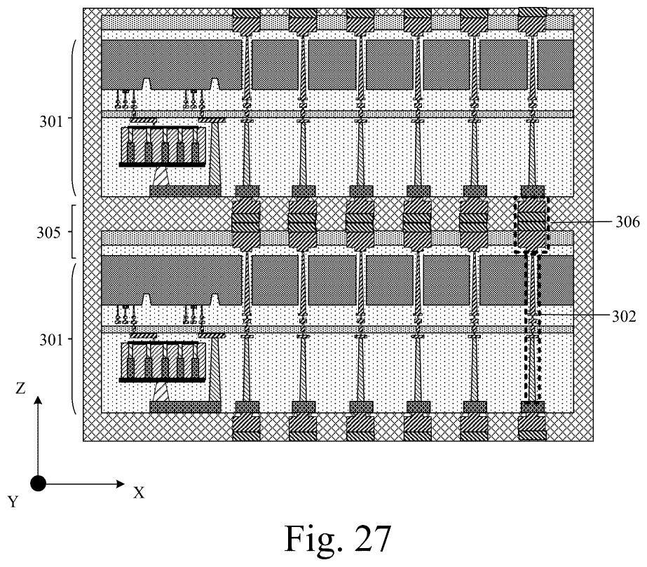

FIGS. 15 to 28 are schematic structural diagrams of a fabrication process of a semiconductor package structure provided by an example of the present disclosure. The method of fabricating the semiconductor package structure provided by the example of the present disclosure will be described below in conjunction with FIGS. 14 to 28.

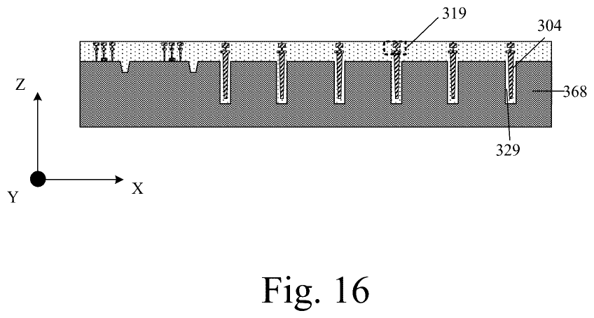

In some examples, as shown in FIGS. 15 and 16, forming the first semiconductor chip includes forming a second semiconductor structure. Forming the second semiconductor structure includes forming a peripheral circuit 324, the second connection structure 304, and a second interconnection sub-structure 319 connected with the second connection structure 304.

In some examples, the forming the second semiconductor structure 322 further includes: forming an initial semiconductor structure 368 extending along a direction perpendicular to the first direction; forming a partial structure of the peripheral circuit 324 in the initial semiconductor structure 368 in the memory region A; and forming a second connection structure 304 extending into the initial semiconductor structure 368 in the contact region B along the first direction.

In an example, as shown in FIG. 15, forming the second semiconductor structure 322 comprises: forming a peripheral circuit 324 in the initial semiconductor structure 368; and as shown in FIG. 16, forming the second connection structure 304 and the second interconnection sub-structure 319 connected with the second connection structure 304, where the second connection structure 304 extends into the initial semiconductor structure 368 along the first direction and is spaced apart from the initial semiconductor structure 368 through an isolation layer 329. Before or while forming the second connection structure 304 and the second interconnection sub-structure 319, an interconnection structure for leading out a gate, a source and a drain of a CMOS transistor in the peripheral circuit 324 may be further formed.

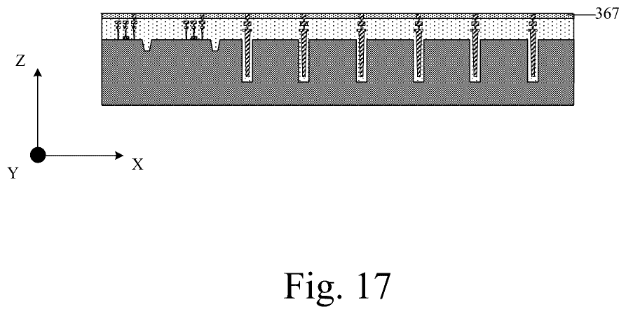

In some examples, with reference to FIG. 17, forming the first semiconductor chip 301 includes forming a second bonding sub-layer 367 on one of two opposite sides of the second semiconductor structure 322 along the first direction. The second bonding sub-layer 367 may include a plurality of bonding structures, such as a bonding structure coupled with the peripheral circuit 324 and a bonding structure coupled with the second connection structure 304.

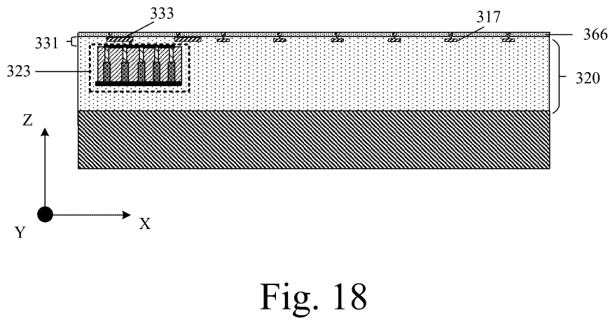

In some examples, with reference to FIG. 18, forming the first semiconductor chip 301 includes forming a first semiconductor structure 320 on a substrate. Forming the first semiconductor structure 320 includes: forming a memory array 323 and a first interconnection sub-structure 317; and forming a first bonding sub-layer 366 on one of two opposite sides of the first semiconductor structure 320 along the first direction.

In some particular examples, with reference to FIGS. 8, 9 and 18 in combination, forming the memory array 323 includes forming a plurality of memory cells 337. The memory cell 337 includes a capacitor structure 338 and a transistor structure 339 arranged as being stacked along the first direction. The capacitor structure 338 includes a first plate 340, a second plate 341, and a dielectric layer 342 between the first plate 340 and the second plate 341. The transistor structure 339 includes a gate structure 343 and a semiconductor body 344 extending along the first direction. One of two opposite ends of the semiconductor body 344 along the first direction is connected with the first plate 340 of the capacitor structure 338. The second plate 341 of the capacitor structure 338 is coupled with the first interconnection line 334. The semiconductor body 344 includes a first electrode structure 345, a channel structure 346 and a second electrode structure 347 arranged sequentially along the first direction. The gate structure 343 is located on at least one side of the channel structure 346 along the direction perpendicular to the first direction. The gate structures 343 of a plurality of transistor structures 339 arranged along a third direction are connected to form a word line structure extending along the third direction. The third direction is perpendicular to the first direction.

As shown in FIG. 8, the transistor structure 339 further includes a gate dielectric layer 370 between the gate structure 343 and the channel structure 346. The gate dielectric layer 370 may include at least one of a high dielectric constant material, silicon oxide, silicon nitride and silicon oxynitride, where the high dielectric constant material may include at least one of hafnium oxide, hafnium silicon oxide, lanthanum oxide, zirconium oxide, zirconium silicon oxide, tantalum oxide, titanium oxide, barium strontium titanium oxide, barium titanium oxide, strontium titanium oxide, lithium oxide, aluminum oxide, lead scandium tantalum oxide, and lead zinc niobate.

In some examples, with FIGS. 17, 18 and 19 in combination, forming the first semiconductor chip 301 includes bonding the first bonding sub-layer 366 with the second bonding sub-layer 367 to form a first bonding layer 321 between the first semiconductor structure 320 and the second semiconductor structure 322. The first bonding layer 321 includes a first bonding structure 318 and a second bonding structure 325. The memory array 323 is coupled with the peripheral circuit 324 through the second bonding structure 325. The first interconnection sub-structure 317 is coupled with the second interconnection sub-structure 319 through the first bonding structure 318. The first interconnection sub-structure 317, the second interconnection sub-structure 319 and the first bonding structure 318 constitute the interconnection structure 369.

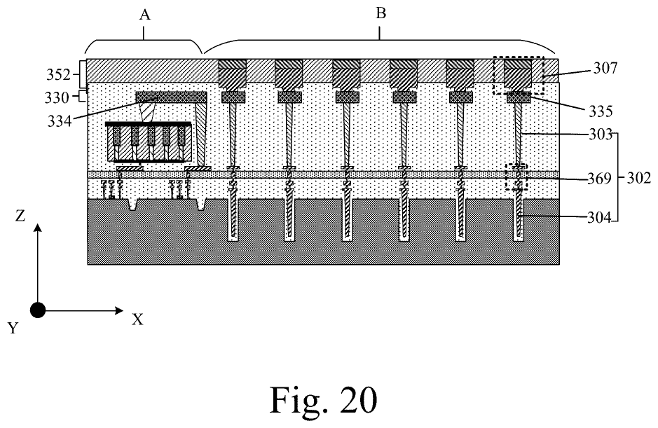

In some examples, with reference to FIG. 20, forming the first semiconductor chip 301 includes forming the first connection structure 303 in the first semiconductor structure 320. The first connection structure 303 is connected with the first interconnection sub-structure 317.

In some examples, as shown in FIG. 18, the forming the first semiconductor structure 320 further includes forming a wiring layer 331 on one of two opposite sides of the memory array 323 along the first direction. The wiring layer 331 extends from the memory region A into the contact region B along the direction perpendicular to the first direction, and includes the first interconnection sub-structure 317 and a first wiring 333.

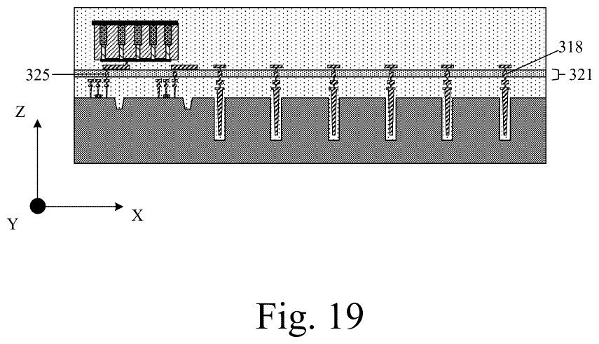

In some examples, with reference to FIG. 19 and FIG. 20, forming the first semiconductor chip 301 includes: removing the substrate; and forming the first connection structure 303 in the first semiconductor structure 320. The first connection structure 303 is connected with the first interconnection sub-structure 317. The first connection structure 303, the interconnection structure 369 and the second connection structure 304 constitute a first conductive structure 302.

In an example of the present disclosure, the first connection structure 303 and the second connection structure 304 in the first conductive structure 302 may be formed separately. In an example, the second connection structure 304 may be formed while the second semiconductor structure 322 is formed. The first connection structure 303 may be formed after the first bonding layer 321 is formed. It will be appreciated that each of forming processes of the first connection structure 303 and the second connection structure 304 may include: etching an insulation material to form a through hole extending along the first direction, and filling a conductive material in the through hole. Separately forming the first connection structure 303 and the second connection structure 304 may reduce the depth of the through hole formed in one etching process. Thus, a difference between a top size and a bottom size of the through hole may be better controlled. The reliability of the formed connection structure is improved while the process difficulty is reduced.

In some particular examples, with continued reference to FIG. 20, forming the first semiconductor chip 301 includes forming a third connection structure 336 extending along the first direction while forming the first connection structure 303. While the first connection structure 303 is formed, the third connection structure 336 extending along the first direction is formed. Two opposite ends of the third connection structure 336 along the first direction are connected with the first wiring 333 and the first interconnection line 334, respectively.

In an example of the present disclosure, the forming process of the first connection structure 303 and the forming process of the third connection structure 336 may be integrated together. Thus, the process operations may be reduced, and the production cost may be saved.

In some examples, as shown in FIG. 20, the forming the first semiconductor chip 301 further includes forming a first pad-out layer 330 on one of two opposite sides of the first connection structure 303 along the first direction away from the second connection structure 304 and on one of two opposite sides of the memory array 323 along the first direction away from the peripheral circuit 324. The first pad-out layer 330 includes a first interconnection line 334 and a first lead-out pad 335. One of two opposite ends of one of the first lead-out pads 335 along the first direction is connected with one of the first connection structures 303. The first interconnection line 334 is coupled with both the memory array 323 and the peripheral circuit 324.

In some particular examples, with reference to FIGS. 8, 9 and 20 in combination, after the first pad-out layer 330 is formed, the second plate 341 of the capacitor structure 338 is coupled with the first interconnection line 334.

In some examples, as shown in FIG. 20, the first semiconductor chip 301 includes a memory region A and a contact region B arranged in juxtaposition along the direction perpendicular to the first direction. The at least one first conductive structure 302 is located in the contact region B. The memory array 323 and the peripheral circuit 324 are located in the memory region A.

In some examples, as shown in FIG. 20, forming the first bump connection layer includes forming a first bump connection sub-layer 352 on one of two opposite sides of the first pad-out layer 330 along the first direction away from the second semiconductor structure 322. The first bump connection sub-layer 352 includes a first bump 307.

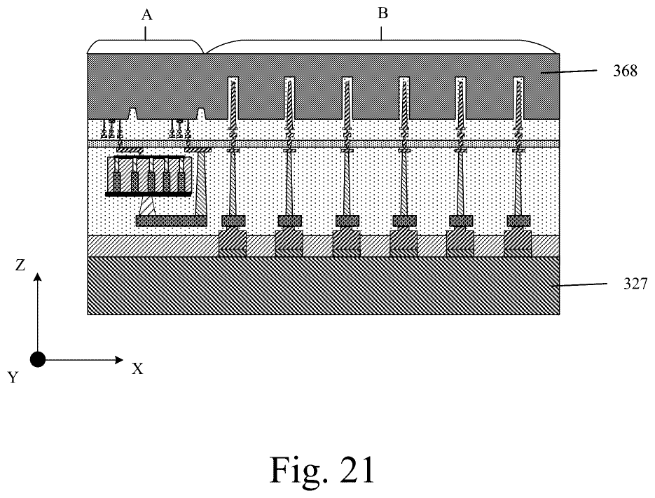

In some particular examples, as shown in FIG. 21, forming the first semiconductor chip 301 further includes: stacking a carrier wafer 327 on the first bump connection sub-layer 352; and turning over the first semiconductor chip 301 such that the initial semiconductor structure 368 is located there above.

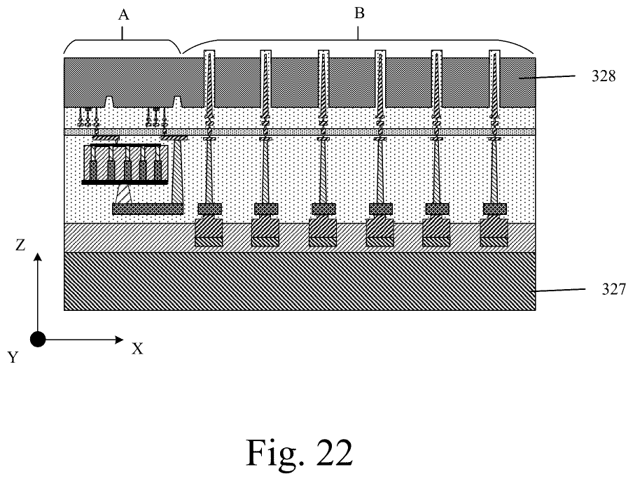

In some examples, as shown in FIG. 22, the forming the first semiconductor chip 301 further includes: removing part of the initial semiconductor structure 368 from one of two opposite sides of the initial semiconductor structure 368 along the first direction away from the first semiconductor structure 320 to expose the second connection structure 304 and form a semiconductor layer 328.

In some particular examples, part of the initial semiconductor structure 368 may be removed first through a grinding process, and then part of the initial semiconductor structure 368 may be further removed through a wet etching process to form the semiconductor layer 328 such that a bottom of the second connection structure 304 surrounded by the isolation layer 329 protrudes relative to the semiconductor layer 328.

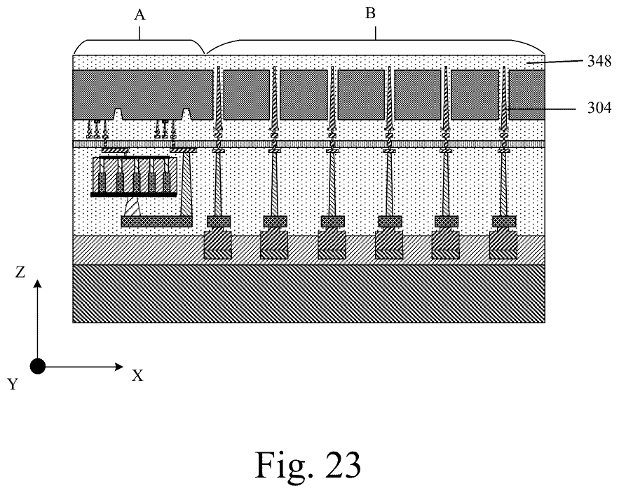

In some particular examples, as shown in FIG. 23, the forming the first semiconductor chip 301 further includes forming a first dielectric layer 348 on the semiconductor layer 328 through a deposition process such that a top surface is flush. The first dielectric layer 348 covers the semiconductor layer 328 and the second connection structure 304. A material of the first dielectric layer 348 includes, but is not limited to, silicon nitride and silicon oxide.

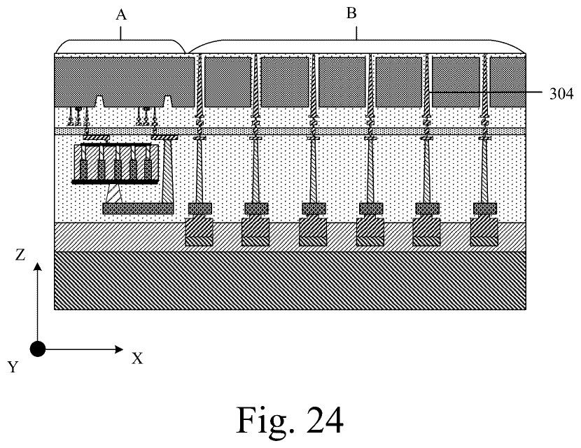

In some particular examples, as shown in FIG. 24, the first dielectric layer 348 is thinned through a chemical mechanical polishing (CMP) process such that the bottom of the second connection structure 304 is exposed.

In an example of the present disclosure, the deposition process includes, but is not limited to, chemical vapor deposition (CVD), low pressure chemical vapor deposition (LPCVD), plasma enhanced chemical vapor deposition (PECVD), physical vapor deposition (PVD), and atomic layer deposition (ALD). The etching process includes, but is not limited to, plasma etching (PE), sputtering etching (SE), ion beam etching (IBE) and reactive ion etching (RIE).

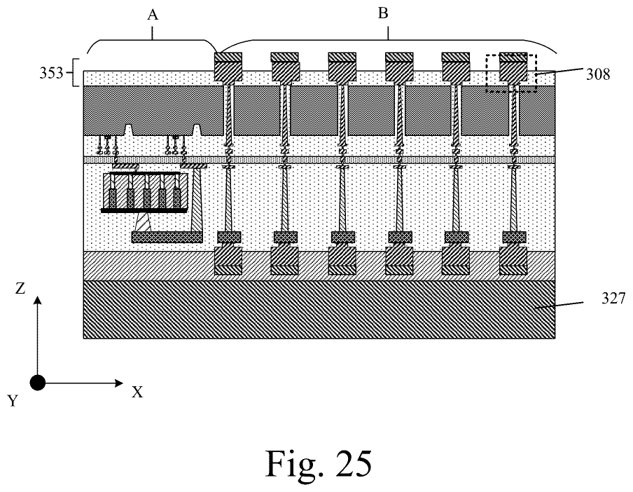

In some examples, with reference to FIGS. 25 to 27, forming the first bump connection layer 305 further includes: forming a second bump connection sub-layer 353 on one of two opposite sides of the semiconductor layer 328 along the first direction away from the first semiconductor structure 320; and bonding the first bump connection sub-layer 352 on one of the first semiconductor chips 301 with the second bump connection sub-layer 353 on other one of the first semiconductor chips 301 to form the first bump connection layer 305 between two adjacent ones of the first semiconductor chips 301. The other one of two opposite ends of one of the first lead-out pads 335 along the first direction is connected with one of the first bump structures 306. The second bump connection sub-layer 353 includes a second bump 308.

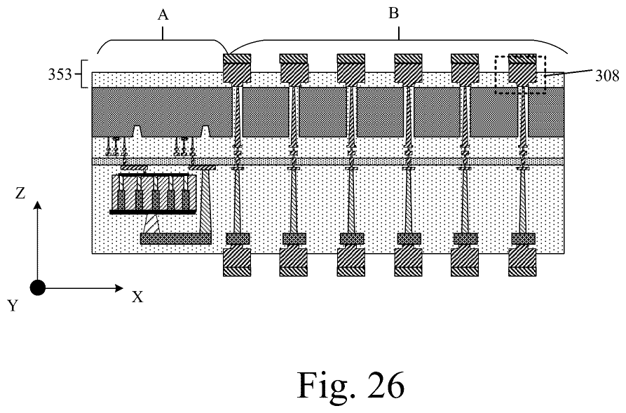

In some particular examples, with reference to FIG. 26, forming the first semiconductor chip 301 further includes removing the carrier wafer 327.

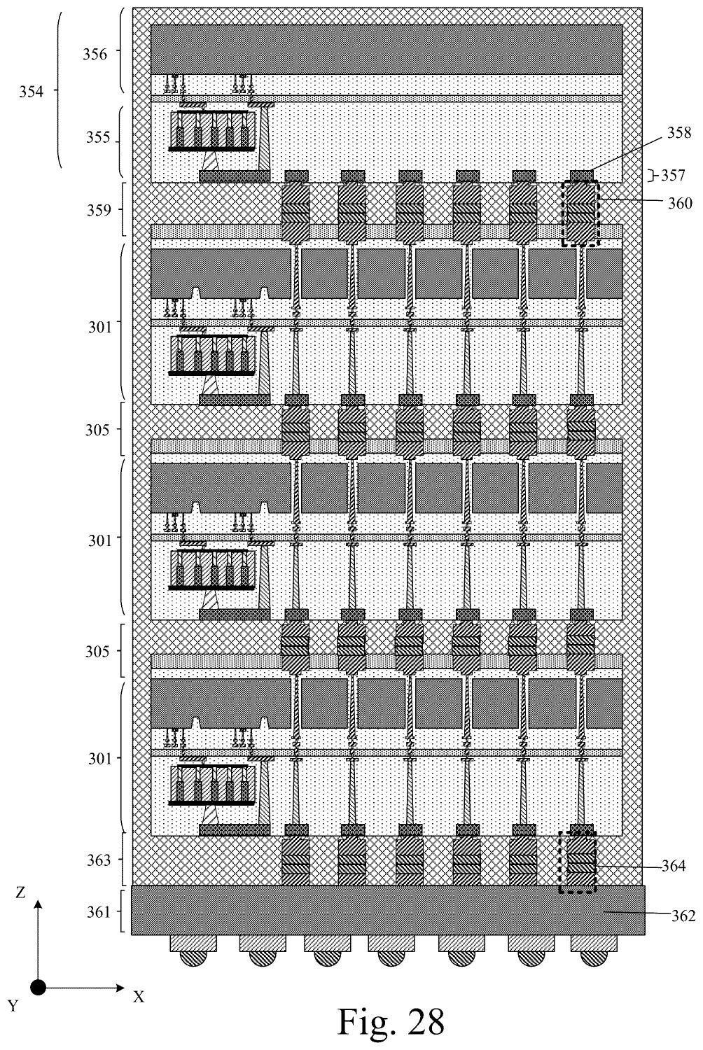

In some examples, with reference to FIG. 28, the method of fabricating the semiconductor package structure further includes: forming a second semiconductor chip 354, where the second semiconductor chip 354 includes a third semiconductor structure 355 and a fourth semiconductor structure 356 arranged as being stacked along the first direction, and one of two opposite sides of the third semiconductor structure 355 along the first direction away from the fourth semiconductor structure 356 includes a third pad-out layer 357 that includes at least one third lead-out pad 358; stacking the second semiconductor chip 354 on the plurality of first semiconductor chips 301; and forming a second bump connection layer 359 between the first semiconductor chip 301 closest to the second semiconductor chip 354 and the second semiconductor chip 354. The third semiconductor structure 355 is located between the fourth semiconductor structure 356 and the first semiconductor chip 301. The second bump connection layer 359 includes at least one second bump structure 360. The second bump structure 360 is coupled with the third lead-out pad 358 and coupled with the first conductive structure 302.

In some examples, with reference to FIG. 28, the method of fabricating the semiconductor package structure further includes: forming a third semiconductor chip 361 including a control circuit 362; and forming a third bump connection layer 363 between the third semiconductor chip 361 and one of the first semiconductor chips 301. The third bump connection layer 363 includes a third bump structure 364 that is coupled with the first conductive structure 302 and coupled with the control circuit 362. The plurality of first semiconductor chips 301 are located between the second semiconductor chip 354 and the third semiconductor chip 361.

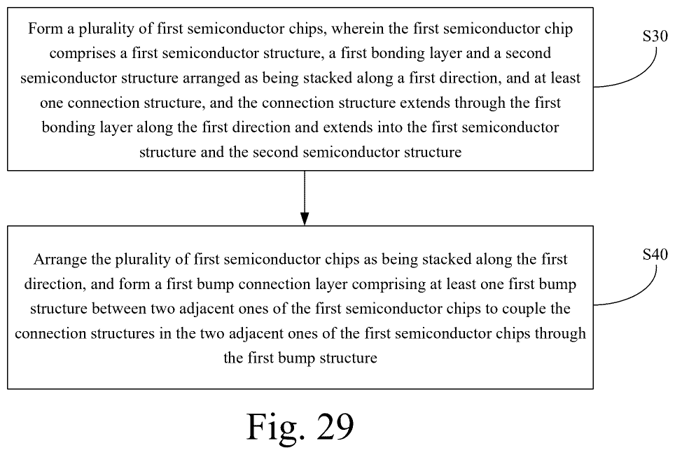

Based on the similar concept to the above-mentioned semiconductor package structure, the present disclosure further provides a method of fabricating a semiconductor package structure. FIG. 29 is a flow diagram of a method of fabricating a semiconductor package structure provided by an example of the present disclosure. The method of fabricating the semiconductor package structure includes:

operation S30: forming a plurality of first semiconductor chips, where the first semiconductor chip includes a first semiconductor structure, a first bonding layer and a second semiconductor structure arranged as being stacked along a first direction, and at least one connection structure, and the connection structure extends through the first bonding layer along the first direction and extends into the first semiconductor structure and the second semiconductor structure;

operation S40: arranging the plurality of first semiconductor chips as being stacked along the first direction, and forming a first bump connection layer including at least one first bump structure between two adjacent ones of the first semiconductor chips to couple the connection structures in the two adjacent ones of the first semiconductor chips through the first bump structure.

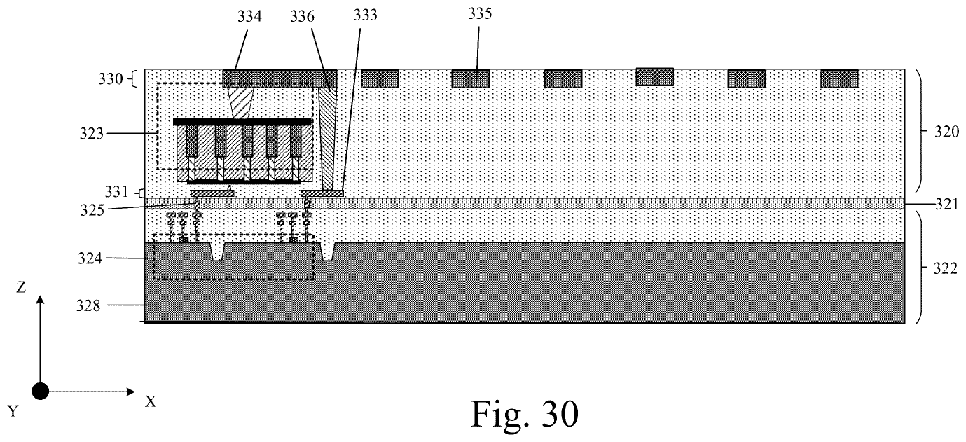

FIGS. 30 to 32 are schematic structural diagrams of a fabrication process of a semiconductor package structure provided by an example of the present disclosure. The method of fabricating the semiconductor package structure provided by the example of the present disclosure will be described below in conjunction with FIGS. 30 to 32. It is to be noted that the fabrication process of the semiconductor package structure is similar to the fabrication process of the semiconductor package structure corresponding to FIGS. 15 to 28. Therefore, the difference between the method of fabricating the semiconductor package structure and the method of fabricating the semiconductor package structure provided by the above example will be primarily described.

In some examples, with reference to FIG. 30, forming the first semiconductor chip 301 includes: forming a first semiconductor structure 320 including a memory array 323; forming a second semiconductor structure 322 including a peripheral circuit 324; and forming a first bonding layer 321 between the first semiconductor structure 320 and the second semiconductor structure 322.

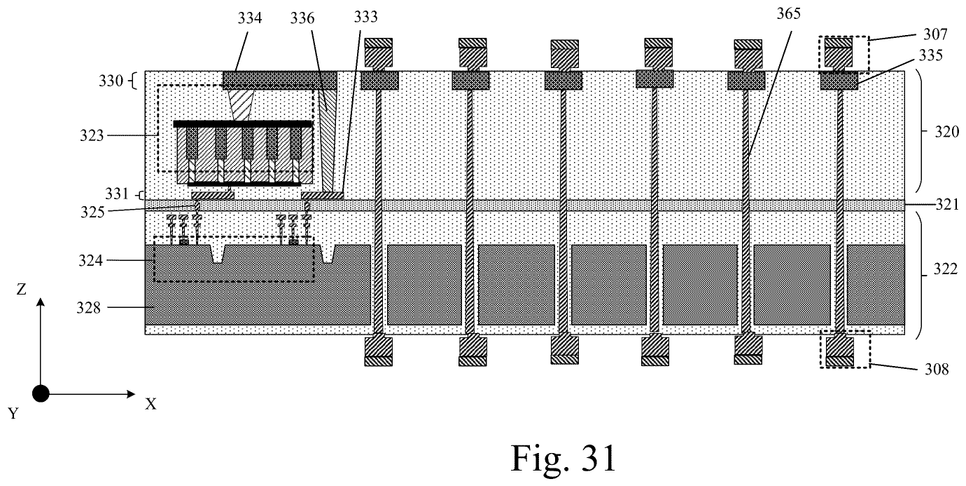

In some examples, with reference to FIG. 31, forming the first semiconductor chip 301 further includes forming at least one connection structure 365 extending along a first direction. The connection structure 365 extends through the first bonding layer 321 and extends into the semiconductor layer 328. A first pad-out layer 330 is formed on a side of the connection structure 365.

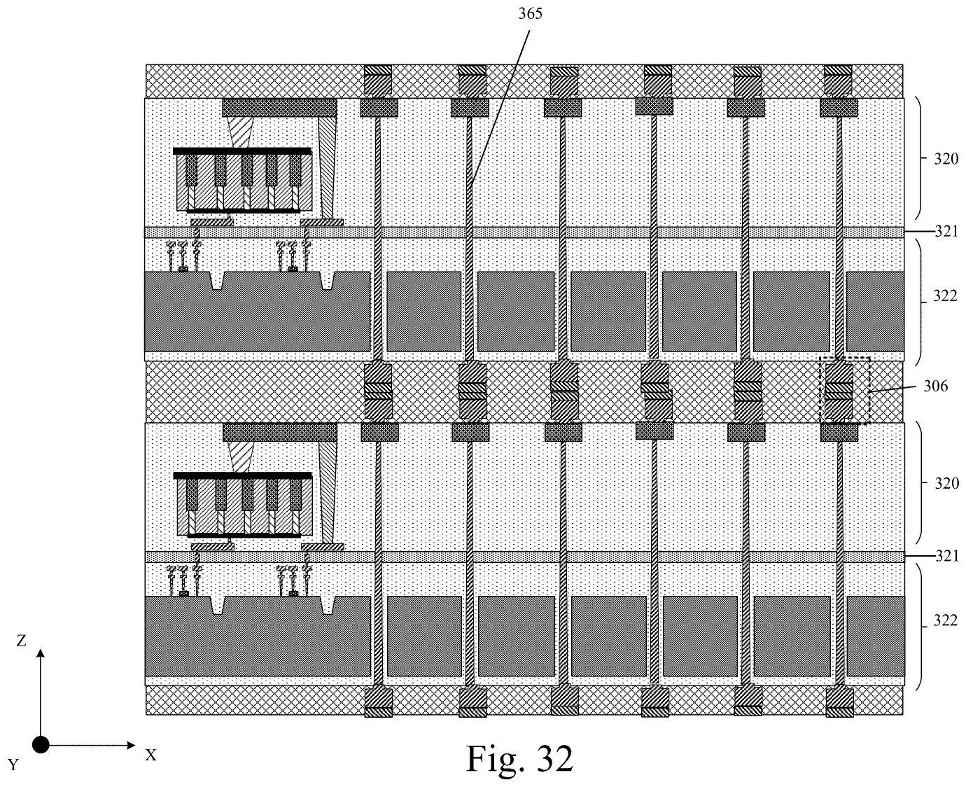

In some examples, with reference to FIG. 32, the method of fabricating the semiconductor package structure includes stacking another first semiconductor chip 301 on the first semiconductor chip 301 such that a first bump 307 in a first bump connection layer 305 is bonded with a second bump 308 in a second bump connection layer 359, thereby forming a first bump structure 306 between two adjacent ones of the first semiconductor chips 301.

In an example of the present disclosure, the connection structure 365 may be formed through one etching process and a conductive material filling process after the first bonding layer 321 is formed between the first semiconductor structure 320 and the second semiconductor structure 322. Thus, process operations may be reduced and contact resistance between different metal materials may be reduced.

The features disclosed in several device examples provided by the present disclosure may be combined arbitrarily to obtain a new device example without conflicts.

The methods disclosed in several method examples provided by the present disclosure can be combined arbitrarily to obtain a new method example without conflicts.

The above descriptions are merely specific implementations of the present disclosure, and the protection scope of the present disclosure is not limited thereto. Any variation or replacement that may be readily figured out by those skilled in the art within the technical scope disclosed by the present disclosure shall fall within the protection scope of the present disclosure.

What is claimed is:

1. A semiconductor package structure, comprising:
a plurality of first semiconductor chips arranged as being stacked along a first direction, wherein the first semiconductor chip comprises at least one first conductive structure, the first conductive structure comprises a first connection structure extending along the first direction, a second connection structure extending along the first direction, and an interconnection structure between the first connection structure and the second connection structure in the first direction; and the interconnection structure is connected with both the first connection structure and the second connection structure; and
a first bump connection layer between two adjacent ones of the first semiconductor chips in the first direction, wherein the first bump connection layer comprises at least one first bump structure, and the first bump structure is coupled with each of the first conductive structures in the two adjacent ones of the first semiconductor chips.

2. The semiconductor package structure of claim 1, wherein the first bump structure comprises a first bump and a second bump stacked along the first direction, the first bump comprises a first portion and a second portion, the second bump comprises a third portion and a fourth portion, the second portion is located between the first portion and the third portion, and the third portion is located between the second portion and the fourth portion.

3. The semiconductor package structure of claim 2, wherein a material of the first portion is different from a material of the second portion, and a material of the third portion is different from a material of the fourth portion.

4. The semiconductor package structure of claim 2, wherein the first portion comprises a first sub-portion and a second sub-portion, the fourth portion comprises a third sub-portion and a fourth sub-portion, the second sub-portion is located between the first sub-portion and the second portion, the third sub-portion is located between the fourth sub-portion and the third portion, a size of the first sub-portion along a second direction is smaller than a size of the second sub-portion along the second direction, a size of the fourth sub-portion along the second direction is smaller than a size of the third sub-portion along the second direction, and the second direction is perpendicular to the first direction.

5. The semiconductor package structure of claim 1, wherein:
the interconnection structure comprises a first interconnection sub-structure, a first bonding structure and a second interconnection sub-structure arranged as being stacked along the first direction, the first interconnection sub-structure is located between the first connection structure and the first bonding structure, and the second interconnection sub-structure is located between the second connection structure and the first bonding structure, and
the first semiconductor chip comprises:
a first semiconductor structure, a first bonding layer and a second semiconductor structure arranged as being stacked along the first direction, wherein the first semiconductor structure comprises the first connection structure, the first interconnection sub-structure and a memory array, the second semiconductor structure comprises the second connection structure, the second interconnection sub-structure and a peripheral circuit, the first bonding layer comprises the first bonding structure and a second bonding structure, and the memory array is coupled with the peripheral circuit through the second bonding structure.

6. The semiconductor package structure of claim 5, wherein:
the first semiconductor chip comprises a memory region and a contact region arranged in juxtaposition along a direction perpendicular to the first direction, the at least one first conductive structure is located in the contact region, and the memory array and the peripheral circuit are located in the memory region, and
the second semiconductor structure comprises:
a semiconductor layer extending along the direction perpendicular to the first direction, wherein a partial structure of the peripheral circuit is located in the semiconductor layer in the memory region, and the second connection structure extends through the semiconductor layer in the contact region along the first direction.

7. The semiconductor package structure of claim 5, wherein the first semiconductor structure further comprises:
a first pad-out layer on one of two opposite sides of the memory array along the first direction away from the peripheral circuit and on one of two opposite sides of the first connection structure along the first direction away from the second connection structure, wherein the first pad-out layer comprises a first interconnection line and a first lead-out pad, two opposite ends of one of the first lead-out pads along the first direction are connected with one of the first connection structures and one of the first bump structures, respectively, and the first interconnection line is coupled with both the memory array and the peripheral circuit.

8. The semiconductor package structure of claim 7, wherein a material of the first connection structure is different from a material of the second connection structure, and a material of the first lead-out pad is different from a material of the first connection structure.

9. The semiconductor package structure of claim 7, wherein a size of one of two opposite ends of the first connection structure in the first direction close to the second connection structure in a second direction is smaller than a size of one of two opposite ends of the first connection structure in the first direction away from the second connection structure in the second direction, a size of one of two opposite ends of the second connection structure in the first direction close to the first connection structure in the second direction is greater than a size of one of two opposite ends of the second connection structure in the first direction away from the first connection structure in the second direction, and the second direction is perpendicular to the first direction.

10. The semiconductor package structure of claim 7, wherein the memory array comprises:
a plurality of memory cells, wherein the memory cell comprises a capacitor structure and a transistor structure arranged as being stacked along the first direction, the capacitor structure comprises a first plate, a second plate, and a dielectric layer between the first plate and the second plate, the transistor structure comprises a gate structure and a semiconductor body extending along the first direction, one of two opposite ends of the semiconductor body along the first direction is connected with the first plate of the capacitor structure, the second plate of the capacitor structure is coupled with the first interconnection line, the semiconductor body comprises a first electrode structure, a channel structure and a second electrode structure arranged sequentially along the first direction, the gate structure is located on at least one side of the channel structure along a direction perpendicular to the first direction, the gate structures of a plurality of transistor structures arranged along a third direction are connected to form a word line structure extending along the third direction, and the third direction is perpendicular to the first direction.

11. A semiconductor package structure, comprising:
a plurality of first semiconductor chips arranged as being stacked along a first direction and a first bump connection layer between two adjacent ones of the first semiconductor chips in the first direction, wherein
the first semiconductor chip comprises a first semiconductor structure, a first bonding layer and a second semiconductor structure arranged as being stacked along the first direction, and at least one connection structure, and the connection structure extends through the first bonding layer along the first direction and extends into the first semiconductor structure and the second semiconductor structure; and
the first bump connection layer comprises at least one first bump structure, and the first bump structure is coupled with each of the connection structures in the two adjacent ones of the first semiconductor chips.

12. The semiconductor package structure of claim 11, wherein the first bump structure comprises a first bump and a second bump stacked along the first direction, the first bump comprises a first portion and a second portion, the second bump comprises a third portion and a fourth portion, the second portion is located between the first portion and the third portion, and the third portion is located between the second portion and the fourth portion.

13. The semiconductor package structure of claim 12, wherein a material of the first portion is different from a material of the second portion, and a material of the third portion is different from a material of the fourth portion.

14. The semiconductor package structure of claim 12, wherein the first portion comprises a first sub-portion and a second sub-portion, the fourth portion comprises a third sub-portion and a fourth sub-portion, the second sub-portion is located between the first sub-portion and the second portion, the third sub-portion is located between the fourth sub-portion and the third portion, a size of the first sub-portion along a second direction is smaller than a size of the second sub-portion along the second direction, and a size of the fourth sub-portion along the second direction is smaller than a size of the third sub-portion along the second direction, and the second direction is perpendicular to the first direction.

15. The semiconductor package structure of claim 11, wherein:
the first semiconductor chip comprises:
a memory region and a contact region arranged in juxtaposition along a direction perpendicular to the first direction, wherein the contact region comprises at least one connection structure, the memory region comprises a memory array and a peripheral circuit arranged as being stacked along the first direction, and at least one second bonding structure between the memory array and the peripheral circuit, the second bonding structure is coupled with both the memory array and the peripheral circuit, the memory array is located in the first semiconductor structure, the peripheral circuit is located in the second semiconductor structure, and the second bonding structure is located in the first bonding layer, and the second semiconductor structure comprises:
a semiconductor layer extending along the direction perpendicular to the first direction, wherein a partial structure of the peripheral circuit is located in the semiconductor layer in the memory region, and the connection structure extends through the semiconductor layer in the contact region along the first direction.

16. The semiconductor package structure of claim 15, wherein:
the first semiconductor structure further comprises:
a first pad-out layer on one of two opposite sides of the memory array along the first direction away from the peripheral circuit and extending from the memory region into the contact region along the direction perpendicular to the first direction, wherein the first pad-out layer comprises a first interconnection line and a first lead-out pad, two opposite ends of one of the first lead-out pads along the first direction are connected with one of the connection structures and one of the first bump structures, respectively, and the first interconnection line is coupled with both the memory array and the peripheral circuit, and
the memory array comprises:
a plurality of memory cells, wherein the memory cell comprises a capacitor structure and a transistor structure arranged as being stacked along the first direction, the capacitor structure comprises a first plate, a second plate, and a dielectric layer between the first plate and the second plate, the transistor structure comprises a gate structure and a semiconductor body extending along the first direction, one of two opposite ends of the semiconductor body along the first direction is connected with the first plate of the capacitor structure, the second plate of the capacitor structure is coupled with the first interconnection line, the semiconductor body comprises a first electrode structure, a channel structure and a second electrode structure arranged sequentially along the first direction, the gate structure is located on at least one side of the channel structure along the direction perpendicular to the first direction, the gate structures of a plurality of transistor structures arranged along a third direction are connected to form a word line structure extending along the third direction, and the third direction is perpendicular to the first direction.

17. A method of fabricating a semiconductor package structure, comprising:
forming a plurality of first semiconductor chips, wherein the first semiconductor chip comprises at least one first conductive structure, the first conductive structure comprises a first connection structure extending along a first direction, a second connection structure extending along the first direction, and an interconnection structure between the first connection structure and the second connection structure in the first direction, and the interconnection structure is connected with both the first connection structure and the second connection structure; and
arranging the plurality of first semiconductor chips as being stacked along the first direction, and forming a first bump connection layer comprising at least one first bump structure between two adjacent ones of the first semiconductor chips to couple the first conductive structures in the two adjacent ones of the first semiconductor chips through the first bump structure.

18. The method of claim 17, wherein forming the first semiconductor chip comprises:
forming a first semiconductor structure, comprising forming a memory array and a first interconnection sub-structure;
forming a first bonding sub-layer on one of two opposite sides of the first semiconductor structure along the first direction;
forming a second semiconductor structure, comprising forming a peripheral circuit, the second connection structure, and a second interconnection sub-structure connected with the second connection structure;
forming a second bonding sub-layer on one of two opposite sides of the second semiconductor structure along the first direction;
bonding the first bonding sub-layer with the second bonding sub-layer to form a first bonding layer between the first semiconductor structure and the second semiconductor structure, wherein the first bonding layer comprises a first bonding structure and a second bonding structure, the memory array is coupled with the peripheral circuit through the second bonding structure, the first interconnection sub-structure is coupled with the second interconnection sub-structure through the first bonding structure, and the first interconnection sub-structure, the second interconnection sub-structure and the first bonding structure constitute the interconnection structure; and
forming the first connection structure in the first semiconductor structure, wherein the first connection structure is connected with the first interconnection sub-structure.

19. The method of claim 18, wherein:
the first semiconductor chip comprises:
a memory region and a contact region arranged in juxtaposition along a direction perpendicular to the first direction, the at least one first conductive structure is located in the contact region, and the memory array and the peripheral circuit are located in the memory region,
the forming the second semiconductor structure further comprises:
forming an initial semiconductor layer extending along the direction perpendicular to the first direction;
forming a partial structure of the peripheral circuit in the initial semiconductor layer in the memory region; and
forming a second connection structure extending into the initial semiconductor layer in the contact region along the first direction, and
the forming the first semiconductor chip further comprises:
removing part of the initial semiconductor layer from one of two opposite sides of the initial semiconductor layer along the first direction away from the first semiconductor structure to expose the second connection structure and form a semiconductor layer.

20. The method of claim 19, wherein the forming the first semiconductor chip further comprises:
forming a first pad-out layer on one of two opposite sides of the first connection structure along the first direction away from the second connection structure and on one of two opposite sides of the memory array along the first direction away from the peripheral circuit, wherein the first pad-out layer comprises a first interconnection line and a first lead-out pad, one of two opposite ends of one of the first lead-out pads along the first direction is connected with one of the first connection structures, and the first interconnection line is coupled with both the memory array and the peripheral circuit.
